(19) United States
(12) Patent Application Publication
(10) Pub. No.: US 2004/0144301 A1
(43) Pub. Date: Jul. 29, 2004

(54) Method for growth of bulk crystals by vapor phase epitaxy

(76) Inventors: Philip G. Neudeck, Olmsted Falls, OH (US); J. Anthony Powell, North Olmsted, OH (US)

Correspondence Address: NASA GLENN RESEARCH CENTER, 21000 BROOKPARK ROAD, OFFICE OF CHIEF COUNSEL; MAIL STOP 500-118, CLEVELAND, OH, 44135, US

(21) Appl. No.: 10/352,552

(22) Filed: Jan. 24, 2003

(51) Int. Cl. C30B 23/00; C30B 25/00; C30B 28/12; C30B 28/14

(52) U.S. Cl. 117/86

(57) ABSTRACT

Methods for vapor phase growth of relatively large bulk single crystals free (or nearly free) of extended structural crystal defects are disclosed. In one embodiment, an initial seed crystal is produced on an atomically-flat crystal surface which does not have to be of the same crystal structure and material as the seed crystal. For the bulk crystal growth, the methods of the present invention primarily utilize a growth mechanism based on crystal nucleation at the edge and corners of crystal facets of the growing crystal. The invention has application in growth of single crystals of wide bandgap semiconducting materials for use in harsh-environment and/or high power electronics and micromechanical systems.

### CROSS REFERENCE TO-RELATED APPLICATIONS

This U.S. patent application Ser. No. ______ having Attorney Docket No. LEW 17,187-1 is related to U.S. patent application Ser. No. 10/198,668.

### ORIGIN OF THE INVENTION

The invention described herein was made by employees of the United States Government and may be used by or for the Government for governmental purposes without payment of any royalties thereon or therefor.

### FIELD OF THE INVENTION

The invention relates to the vapor phase growth of semiconductor bulk crystals, and more particularly, to a method for growing relatively large single crystals free (or nearly free) of extended structural crystal defects. In some embodiments, the invention provides a method for producing the initial seed crystal by heteroepitaxial growth on an atomically-flat crystalline surface. The invention has application in the growth of single crystals of wide-bandgap semiconducting materials for use in harsh-environment and/or high power electronics and micromechanical systems. The semiconductor devices find application in high power, high frequency, high temperature and high radiation environments, as well as use in optoelectronic devices such as lasers and light-emitting diodes.

### BACKGROUND OF THE INVENTION

Semiconductor devices, all types of which are related to the present invention, are used in a wide variety of electronic applications. Semiconductor devices include diodes, transistors, integrated circuits, sensors, and opto-electronic devices, such as light-emitting diodes and diode lasers. Various semiconductor devices using silicon or compound semiconductors, such as gallium arsenide (GaAs) and gallium phosphide (GaP) are commonly used. In order to fabricate semiconductor devices, it is necessary to be able to grow high-quality, low-defect-density single crystal films with controlled impurity incorporation while possessing good surface morphology. The substrate upon which the film is grown should also be a high-quality, low-defect-density single crystal. In recent years, there has been an increasing interest in research on wide-bandgap semiconductors for use in high temperature, high power, high frequency, and/or high radiation operating conditions under which silicon and conventional III-V semiconductors cannot adequately function. Particular research emphasis has been placed on SiC, and III-nitride alloys, including AlN, GaN, InGaN, AlGaN, and others.

Conventional semiconductors are unable to meet some of the increasing demands of the automobile and aerospace industries as they move to smarter and more electronic systems. New wide bandgap (WBG) materials are being developed to meet the diverse demands for more power at higher operating temperatures. Two of the most promising emerging wide bandgap semiconductors are silicon carbide (SiC) and gallium nitride (GaN). At over three electron volts, the bandgap of some of these materials is nearly three times as large as that of silicon. This advantage theoretically translates into very large improvements in power handling capabilities and higher operating temperatures that will enable revolutionary product improvements. Once material-related technology obstacles are overcome, SiC's properties are expected to dominate high power switching and harsh-environment electronics for manufacturing and engine control applications, while GaN will enable high power high frequency microwave systems at frequencies beyond 10 GHz. To date the best SiC devices to our knowledge are homojunction while III-N devices are primarily fabricated in heteroepitaxial films (i.e., SiC or sapphire wafers with device layers of GaN, AlGaN, AlN, etc.) because production of bulk GaN wafers is not practical at the present time.

Silicon carbide crystals exist in hexagonal, rhombohedral and cubic crystal structures. Generally, the cubic structure, with the zincblende structure, is referred to as β-SiC or 3C—SiC, whereas numerous polytypes of the hexagonal and rhombohedral structures are collectively referred to as α-SiC. To our knowledge, only bulk (i.e., large) crystals of the α polytypes have been with sufficient quality for electronic devices grown to date: the β (or 3C) polytype can only be obtained as small (less than 1 cm²) blocky crystals or thick epitaxial films on small 3C substrates or crystal films of poor quality (high dislocation density) grown heteropitaxially on some other substrate. The most commonly available α-SiC polytypes are 4H—SiC and 6H—SiC; these are commercially available as polished wafers, presently up to 75 mm in diameter. Each of the SiC polytypes has its own specific advantages over the others. For example, (1) 4H—SiC has a significantly higher electron mobility compared to 6H—SiC; (2) 6H—SiC is used as a substrate for the commercial fabrication of GaN blue light-emitting diodes (LEDs); and (3) 3C—SiC has a high electron mobility similar to that of 4H and may function over wider temperature ranges, compared to the a polytypes, but 3C—SiC crystals of sufficient quality and size for beneficial electronic devices have not previously been available.

Silicon carbide polytypes are formed by the stacking of double layers (also referred to as bilayers) of Si and C atoms. Each double layer may be situated in one of three positions known as A, B, and C. The sequence of stacking determines the particular polytype; for example, the repeat sequence for 3C is ABCABC . . . (or ACBACB . . . ) the repeat sequence for 4H is ABACABAC . . . and the repeat sequence for 6H is ABCACBABCACB . . . . From this it can be seen that the number in the polytype designation gives the number of double layers in the repeat sequence and the letter denotes the structure type (cubic, hexagonal, or rhombohedral). The stacking direction is designated as the crystal c-axis and is in the crystal <0001> direction; it is perpendicular to the basal plane which is the crystal (0001) plane. The (111) plane of the cubic structure is equivalent to the (0001) plane of the α polytypes. The SiC polytypes are polar in the <0001> directions; in one direction, the crystal face is terminated with silicon (Si) atoms; in the other direction, the crystal face is terminated with carbon (C) atoms. These two faces of the (0001) plane are known as the Si-face and C-face, respectively.

The 3C—SiC (i.e., cubic) polytype has four equivalent stacking directions, and thus there are four equivalent planes, the set of four {111} planes, that are basal planes. Herein, any of the set {111} planes shall be referred to as a (111) plane. Herein, the term “cubic crystal” shall also refer to crystals with the zincblende structure and to crystals with the diamond cubic structure. Crystals with either of these crystal structure have tetrahedral bonding. As used herein, “basal plane” shall refer to either the (0001) plane for a α-SiC, or the (111) plane of 3C—SiC or the (111) plane of any crystal with the cubic structure. The term “vicinal (0001) wafer” shall be used herein for wafers whose polished surface (the growth surface) is misoriented less than 10° from the basal plane. The term “mesa” is meant to represent an isolated growth region. The term “platelet seed crystal” is meant to represent a SiC crystal grown by the Lely process more fully described in U.S. Pat. No. 2,854,364, entitled “Sublimation Process for Manufacturing Silicon Carbide Crystals”, of Jan Anthony Lely and issued Sep. 30, 1958. The angle of misorientation of a crystal surface from the (0001) plane shall be referred to herein as the tilt angle. The term “homoepitaxial” shall be referred to herein as epitaxial growth, whereby the film and the substrate (wafer) are of the same polytype and material, and the term “heteroepitaxial” shall be referred to herein as epitaxial growth whereby the film is of a different polytype or material than the substrate. The term “bilayer” shall be referred to herein as a layer along the basal plane consisting of two-tightly bonded monolayers of atoms, such as Si and C atoms tightly bonded in bilayers of SiC to be further described. The term “defect free” shall be referred to herein as a single crystal that is free of extended structural defects, such as dislocations that propagate over numerous atoms in at least one direction. The term “defect free” is not meant to describe isolated point defects that involve at most 1 or 2 atoms at an isolated 3D point in the crystal, such as atomic vacancy point defects, interstitial point defects, and impurity point defects.

Current theories explaining epitaxial single-crystal growth are well known. Crystal growth can take place by several mechanisms. Two of these are: (1) growth can take place by the lateral growth of existing atomic-scale steps on the surface of a substrate and (2) growth can take place by the formation of two-dimensional atomic-scale nuclei on the surface followed by lateral growth from the steps formed by the nuclei. The lateral growth from steps is sometimes referred to as “step-flow growth.” In the first mechanism, growth proceeds by step-flow from existing steps without the formation of any two-dimensional nuclei (i.e., without 2D nucleation). In the nucleation mechanism, the nucleus must reach a critical size in order to be stable: in other words, a potential energy barrier must be overcome in order for a stable nucleus to be formed. Contamination or defects on the substrate surface can lower the required potential energy barrier at a nucleation site. In the processes described in U.S. Pat. No. 5,915,194 (sometimes herein referred to as '194) having certain drawbacks related to stacking faults as more fully described in the cross-referenced U.S. Pat. No. 6,488,771, (sometimes herein referred to as '771), crystal growth proceeds by (1) step flow without 2D nucleation or by (2) step-flow with 2D nucleation. Step-flow growth with 2D nucleation allows the growth of epitaxial films of any desired thickness. In the processes described in '771, optimum growth (i.e., defect free) occurs when a first bilayer and then a second bilayer are completed from lateral step-flow expansion of single nucleation islands on an atomically-flat surface.

As discussed above, as well as in U.S. Pat. No. 5,915,194, 3C—SiC, to our knowledge, is not available in high quality single-crystal large wafer form. Hence, 3C—SiC device structures must be grown heteroepitaxially on some other substrate material. The invention described in the '771 patent overcomes the problems of U.S. Pat. No. 5,915,194, ('194) to realize the growth of high quality low-defect 3C—SiC films on 6H—SiC and 4H—SiC substrates. However, the invention of the '771 patent is not suitable for the growth of large bulk crystals because of low growth rates and extended growth that eventually leads to detrimental coalescence with the surrounding hexagonal substrate material.

With regard to single crystal silicon carbide (SiC), significant advances have been made in recent years in developing the hexagonal polytypes of SiC, as 4H—SiC and 6H—SiC wafers, epilayers, and devices are being improved and commercialized. Despite the partial success achieved with hexagonal SiC, significant fundamental materials problems persist that severely hinder commercialization and beneficial system insertion of SiC-based electronics. One of the most intransigent of these problems is the high dislocation density in SiC wafers and epilayers in which electronic devices are constructed. These dislocations harm the performance, reliability, and reproducibility of SiC electronic devices, and are therefore hindering the development and commercialization of useful SiC semiconductor devices. Unfortunately, a high density of screw dislocations seems inherent to the physical vapor transport (PVT) seeded sublimation process commonly used to grow large single-crystal boules of the hexagonal polytypes of SiC, which are then subsequently sawed and processed into SiC wafers used for electronic device fabrication. To date, variations of the PVT seeded sublimation process have been the only method that has been employed to mass-produce and commercialize electronic quality single-crystal SiC wafers compatible with standard semiconductor wafer fabrication equipment and methods. This method for growing large reproducible crystals of the non-cubic polytypes of SiC relies on the presence of screw dislocations to provide steps to grow the crystal along the c-axis maintaining a uniform polytype. The mechanism of dislocation assisted crystal growth is well known and documented in prior art. In addition to screw dislocations, non-cubic polytype SiC crystals produced by the seeded sublimation method are also plagued with numerous dislocations that lie along, the basal plane of the crystal. No method for mass producing large, reproducible single-crystals of SiC without dislocations exists to our knowledge in the prior art. This same predicament (i.e., no method of producing large single-crystals without dislocations) also plagues diamond, III-N, and other crystal materials with a broad variety of useful applications.

S. N. Gorin and L. M. Ivanova describe the growth of 3C—SiC crystals in a technical paper entitled, “Cubic Silicon Carbide (3C—SiC): Structure and Properties of Single Crystals Grown by Thermal Decomposition of Methyl Trichlorosilane in Hydrogen”, Phys. Stat. Sol. (b), Vol. 202, pp. 221-245, (1997). These individuals grew crystals of 3C—SiC on a heated rod of graphite using chemical vapor deposition. This produced multiple seed crystals each with numerous twin planes (e.g. planar dislocation). As the seed crystals grew, the twin planes propagated throughout the growing crystals and this resulted in crystals with poor morphology and numerous planar dislocations.

Hiroyuki Nagasawa, Takamitsu Kawahara, and Kuniaki Yagi describe the growth of 3C—SiC films on Si in a technical paper entitled, “Heteroepitaxial Growth and Characteristics of 3C—SiC films on Large Diameter Si (0001) Substrates”, Materials Science Forum, vols. 389-393, pp. 319-322 (2002). These individuals grew 3C—SiC films on “undulant” grooved single-crystal (001)Si substrates using chemical vapor deposition. A high density of planar defects was generated at the film/substrate boundary, and the density decreased as the thickness of the films increased. However, the defect density did not decrease to zero, as planar defects along certain directions could not be eliminated with this process.

Philip R. Tavernier and David R. Clarke describe a process for making GaN seed crystals in a technical paper entitled, “Progress Toward Making Gallium Nitride Seed Crystals Using Hydride Vapor-Phase Epitaxy”” J. Am. Ceram. Soc., vol. 85, no. 1, pp. 49-54 (2002). These individuals describe a technique for producing seed crystals of GaN for subsequent growth into bulk crystals of GaN. In their approach, a GaN film is grown heteroepitaxially on a sapphire substrate by vapor-phase process; then the GaN film is removed from the substrate. The separated GaN film is used as a seed crystal for further GaN growth. The process as reported produces seed crystal with a high density of defects, such as threading dislocations. These defects are incorporated into any bulk crystal grown from the seed crystal.

N. Zaitseva, I. Smolsky, and L. Carman describe crystal growth mechanisms in a technical paper entitled, “Growth Phenomena in the Surface Layer and Step Generation from the Crystal Edges”, J. of Crystal Growth, vol. 222, pp. 249-262 (2001). These authors propose a crystal growth mechanism involving step generation from the edge of crystal facets. This proposal was based on experimental observations of the solution growth (i.e., growth from a liquid phase) of potassium dihydride phosphate (KDP) crystals at near room-temperature conditions. These authors concluded that steps were generated at crystal facet edges in response to a deviation of the crystal facets from their exact crystallographic orientation (i.e. in response to a deviation from a condition of singularity). The authors suggest that dislocation step sources can be a cause for the deviation from singularity. Hence, the authors conclude that edge generation of steps works in combination with the dislocation generation of steps. The authors do not suggest that edge generation by itself (i.e., in the absence of dislocation step sources) is a mechanism for the bulk crystal growth. The authors further state that observations made in the process of the development of rapid growth show that dislocation growth remains a dominant mechanism even at very high super saturation.

As yet, to our knowledge, there is no prior art process for producing defect-free (or nearly defect-free) bulk single crystals of any of the wide bandgap semiconductor materials.

### OBJECTS OF THE INVENTION

It is a primary object of the present invention to provide a vapor-phase method of growing defect-free (or nearly defect-free) bulk single crystals of wide bandgap semiconductor materials with a cubic crystal structure. The method is particularly suited for the growth of 3C—SiC, cubic-GaN, cubic-AlN, and diamond.

It is another object of the present invention to provide a method of growing defect-free (or nearly defect-free) seed crystals with a cubic structure on atomically-flat crystal surfaces.

It is still a further object of the present invention to provide a high growth-rate crystal growth method for the vapor phase growth of wide bandgap semiconductor crystal materials.

It is another object of the present invention to provide a method for controlling which of two rotational variants of a cubic crystal is grown upon a step-free substrate surface.

It is another object of the present invention to provide crystals with lower dislocation densities for the subsequent fabrication of improved semiconductor electronic devices.

It is another object of the present invention to provide a method for controlled growth of crystals with low-index facets.

### SUMMARY OF THE INVENTION

The present invention is directed to a method for growing relatively large single-crystals substantially free of extended structural crystal defects. In one embodiment of the invention, the initial seed crystal is grown heteroepitaxially on an atomically-flat crystal that is not of the same structure and/or material as the seed crystal.

The practice of the present invention, which is particularly related to the formation of defect-free (or nearly defect-free) seed crystals and the growth of defect-free (or nearly defect-free) bulk crystals, is based on our discovery that under specific growth conditions, defect-free (or nearly defect-free) three dimensional (3D) faceted seed crystals of 3C—SiC crystals can be grown at high growth rates on atomically-flat hexagonal SiC. We further discovered that the 3D growth was primarily due to an edge/corner nucleation process in combination with step flow growth rather than a 2D nucleation process followed by step flow growth as proposed in the '194 patent. The edge/corner nucleation process establishes step trains that flow inward from the edge of the crystal facets. We have observed that the edge/corner nucleation process takes place for cubic crystal structure materials, but does not take place for growth of crystals of hexagonal crystal structure. Thus, we have discovered that we cannot grow 3C—SiC heterofilms to have atomically-flat surfaces as taught and claimed in part of the '194 patent. We further discovered that, under specific growth conditions, continued growth of the low-defect seed crystals could be carried out at high growth rates provided the growing 3D crystal was prevented from coalescing with any extraneous growth on either the support structure of the growing crystal or any surrounding surfaces within the growth system.

In general, the invention provides methods for the vapor phase growth of wide bandgap semiconductor bulk single crystals, and more particularly, a method for producing defect-free (or nearly defect-free) bulk crystals of cubic silicon carbide (3C—SiC), cubic aluminum nitride (AlN), cubic gallium nitride (GaN), and other materials or compounds. Specifically, the invention enables the heteroepitaxial vapor phase growth of desired defect-free (or nearly defect-free) cubic seed crystals on atomically-flat hexagonal crystal surfaces. Additionally, the invention enables the homoepitaxial vapor phase growth of defect-free (or nearly defect-free) bulk cubic single crystal starting from any cubic defect-free (or nearly defect-free) seed crystal.

In one embodiment of the invention, a method is provided wherein a defect-free film of a cubic crystal material (e.g., 3C—SiC) is first grown heteroepitaxially on atomically-flat crystalline mesa surfaces of a hexagonal crystalline substrate material (e.g., 6H—SiC) utilizing selected growth conditions according to prior art processes. The atomically-flat surface becomes an interface plane separating the substrate material from the film which becomes a seed crystal for further growth. The method continues with its second step under a second set of selected growth conditions, wherein continued growth of the defect-free 3C—SiC seed crystal is carried out using a growth process wherein the edge/corner nucleation in combination with step flow growth is the dominant crystal growth mechanism. Under these conditions, the initially relatively flat 3C—SiC film (but not atomically-flat) becomes a three-dimensional (3D) faceted crystal. The method continues its third step, wherein, growth is continued under selected conditions wherein the seed crystal grows and expands outward in a manner that none of the additional crystal growth merges with any material either within the growth reactor or the support structure that is supporting the growing crystal. The method continues with its fourth step, wherein the growing seed crystal is separated from the initial hexagonal substrate crystal in a manner that does not introduce any defects in the seed crystal. The method continues with its fifth step, wherein the separated seed crystal is placed in a growth reactor and supported in a manner, wherein additional growth utilizing the edge/corner nucleation in combination with step flow takes place as the dominant growth mechanism and takes place without any of the additional growth merging with any material either within the growth reactor or on the support structure that is supporting the growing crystal. This process of preventing merger or coalescence with extraneous material continues until a defect-free (or nearly defect-free) bulk crystal of desired size is achieved.

In another embodiment of the invention a method is provided, wherein defect-free (or nearly defect-free) seed crystals can be obtained from any defect-free (or nearly defect-free) bulk cubic crystal regardless of its origin. Normally, a desired requirement for this embodiment is that the process for separating seed crystals from a bulk crystal does not introduce defects into the seed crystal that could act as step sources in subsequent growth on the seed crystal. The remainder of this embodiment utilizes the steps described for the first embodiment starting with the fifth step thereof.

### BRIEF DESCRIPTION OF THE DRAWINGS

FIG. 1 is composed of FIGS. 1(A), 1(B), 1(C), 1(D), 1(E), 1(F), 1(G), 1(H), 1(I) 1(J), 1(K), 1(L), 1(M), 1(N), and 1(P) that illustrate various steps, and intermediate results thereof, associated with the method of the present invention, wherein;

FIGS. 1(A) and 1(B) illustrate a cross-sectional view and a top view, respectively, of two atomically-flat mesas on a 6H—SiC wafer,

FIG. 1(C) illustrates a cross-sectional view of 6H—SiC mesas during the initial stage of 3C—SiC growth (defect-free 3C—SiC on the atomically-flat mesas), and low-quality 3C—SiC in the trenches, and illustrating the definition of the “interface plane”,

FIGS. 1(D) and 1(E) illustrate a cross-sectional view D-D′ and a top view, respectively, after faceted homoepitaxial growth has taken place on the initial 3C—SiC growth by an edge/corner nucleation process,

FIGS. 1(F) and 1(G) illustrate a cross-sectional view and a top view, respectively, of two 6H—SiC mesas after 3C—SiC growth if either 3C—SiC or 6H—SiC is grown in the trenches,

FIGS. 1(H) and 1(I) illustrate how a graphitized photoresist pattern in the trenches can retard growth in the trenches during 3C—SiC growth on the atomically-flat 6H—SiC mesas,

FIGS. 1(J) and 1(K) illustrate a cross-sectional view and a backside view, respectively, showing two seed crystal stacks ready to be removed from the initial substrate crystal,

FIG. 1(L) illustrates a cross-sectional view of two seed crystal stacks on a 0.6H—SiC wafer after the backside of the 6H—SiC wafer has been thinned by either a suitable lapping process or an unpatterned backside etch process.

FIGS. 1(M) and 1(N) illustrate a backside view and a cross-sectional view, respectively of two seed crystal stacks that have been removed from a wafer containing multiple mesas with 3C—SiC crystal stacks wherein there is still remnants of the 6H—SiC substrate mesas,

FIGS. 1(P) and 1(Q) illustrate a cross-sectional view and top view, respectively, of the two seed crystal stacks after the entire 6H—SiC substrate crystal has been removed.

FIG. 2 illustrates a cross-sectional view of two seed crystal stacks grown in accordance with the present invention and mounted onto a mechanical support substrate prior to removal of the 6H—SiC substrate wafer from the crystal stacks.

FIG. 3 is composed of FIGS. 3(A) and 3(B) which illustrate a cross-sectional view and a backside view, respectively, of a 6H—SiC wafer (with two mesas containing defect-free 3C—SiC crystal stacks) after the etching of postholes on the backside of the wafer so that each mesa can be subsequently removed and then mounted for further growth on the 3C—SiC crystal stacks.

FIG. 4 is composed of FIGS. 4(A) and 4(B), wherein;

FIG. 4(A) illustrates growth on a growing bulk crystal and on a movable baffle that hinders or prevents material deposition in the vicinity of the support structure, and

FIG. 4(B) illustrates that as additional growth occurs on the baffle, the baffle is moved away from the growing crystal and seed crystal so that material deposition on the baffle does not coalesce with the growth on the growing crystal.

FIG. 5 is composed of FIGS. 5(A) and 5(B), wherein;

FIG. 5(A) illustrates two gas flows directed toward the growing bulk crystal that is supported on a support structure whereby gas flow no. 1 contains a carrier gas and precursors for the growth of the crystal and gas flow no. 2 contains only the carrier gas. It should be noted in FIG. 5(A) that gas flow no. 1 is directed onto the growing crystal at a location furthest from the support structure compared to the gas flow no. 2, and

FIG. 5(B) illustrates the growing bulk crystal further along in the growth process from that of FIG. 5(A).

FIG. 6 illustrates six equivalent <1100> directions and two sets (A and B) of three <1100> directions with angular separation of 120 degrees.

FIG. 7 is composed of 7A, 7B, 7C, and 7D, wherein;

FIG. 7A illustrates a top view of steps produced on a mesa shaped like an equilateral triangle oriented with sides perpendicular to the A set of <1100> crystallographic directions with 120 degrees of angular separation;

FIG. 7B illustrates a top view of steps produced on a mesa shaped like an equilateral triangle oriented with sides perpendicular to the B set of <1100> crystallographic directions with 120 degrees of angular separation;

FIG. 7C is a cross-sectional view of the steps on the 4H—SiC triangular mesas of FIG. 7A; and

FIG. 7D is a cross-sectional view of the steps on the 4H—SiC triangular mesas of FIG. 7B.

### DETAILED DESCRIPTION OF THE PREFERRED EMBODIMENTS

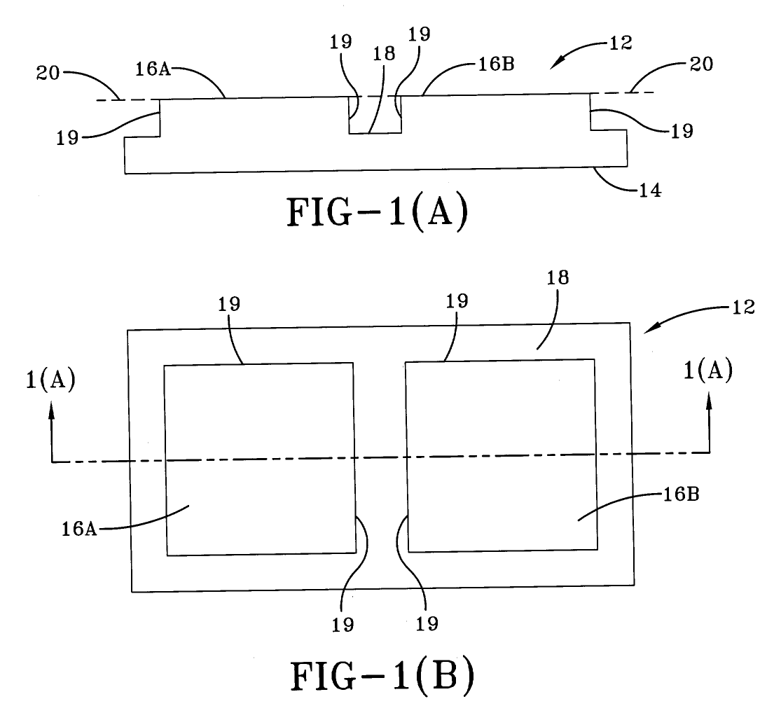

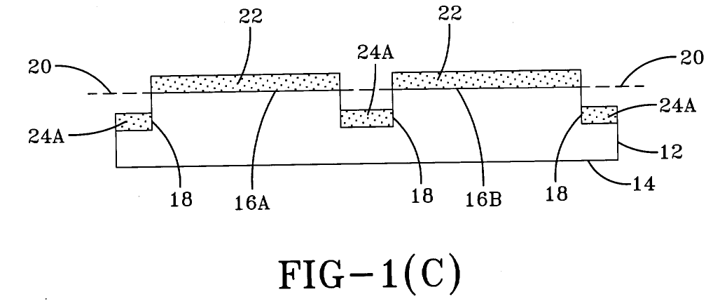

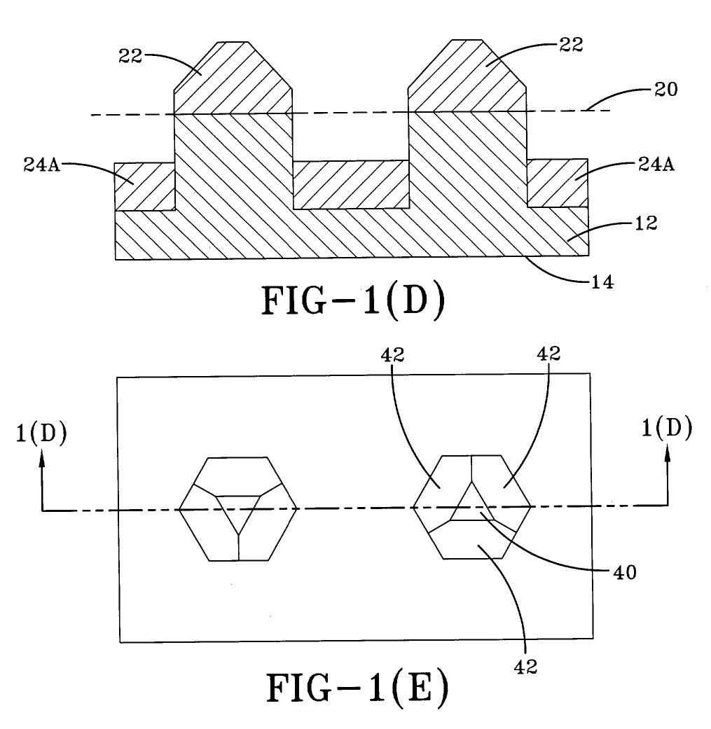

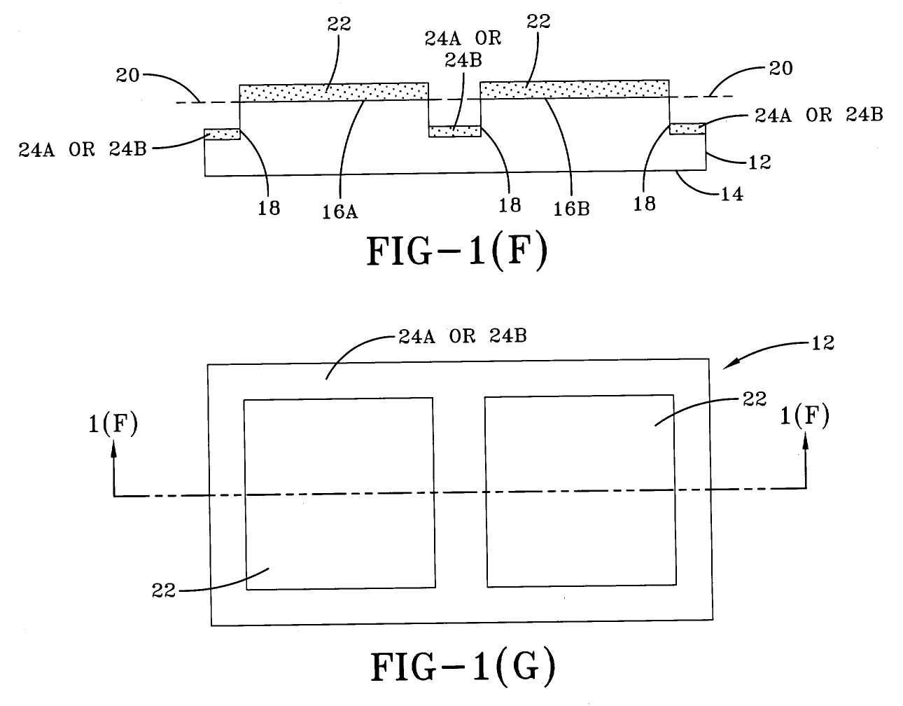

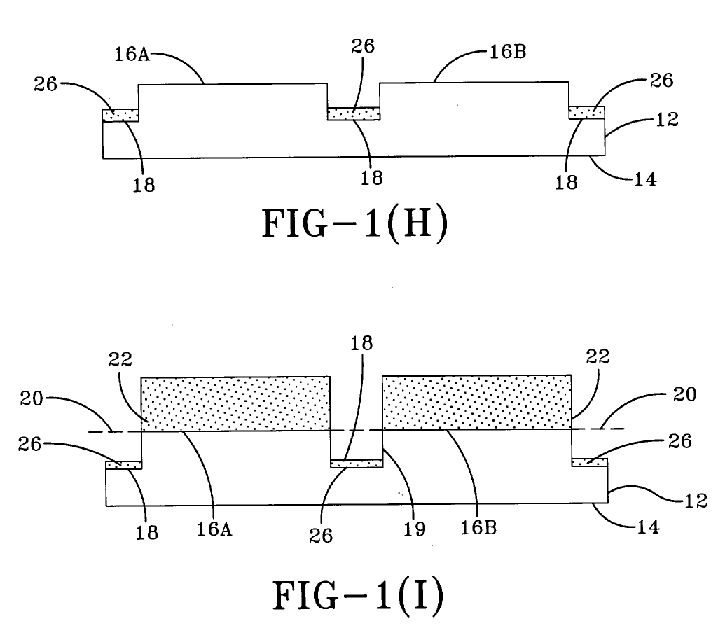

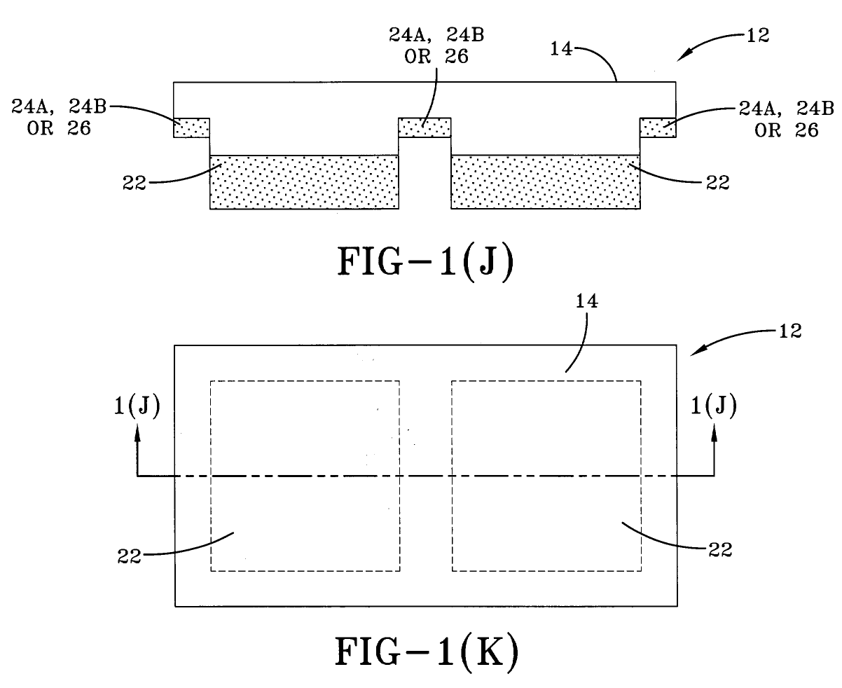

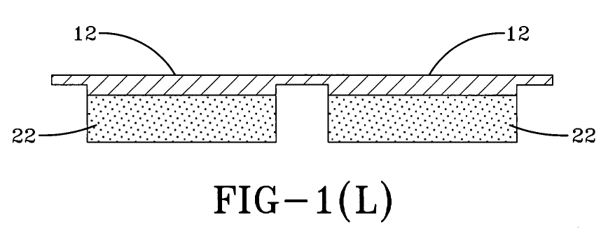

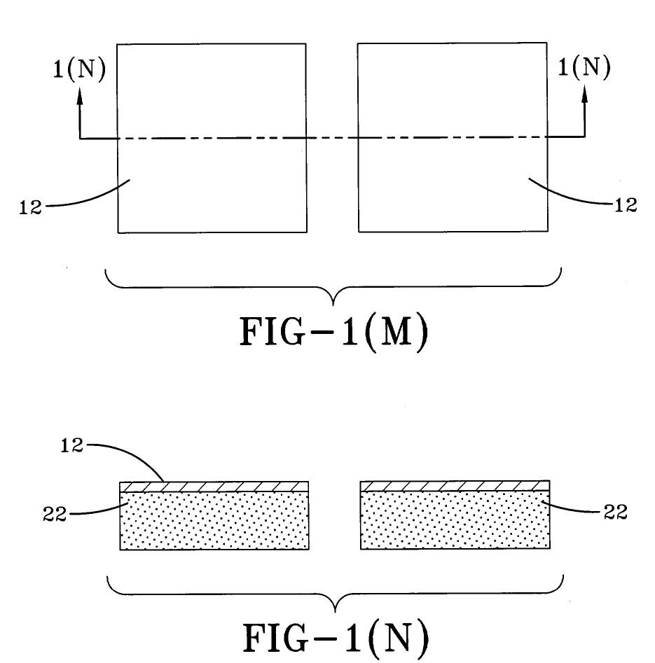

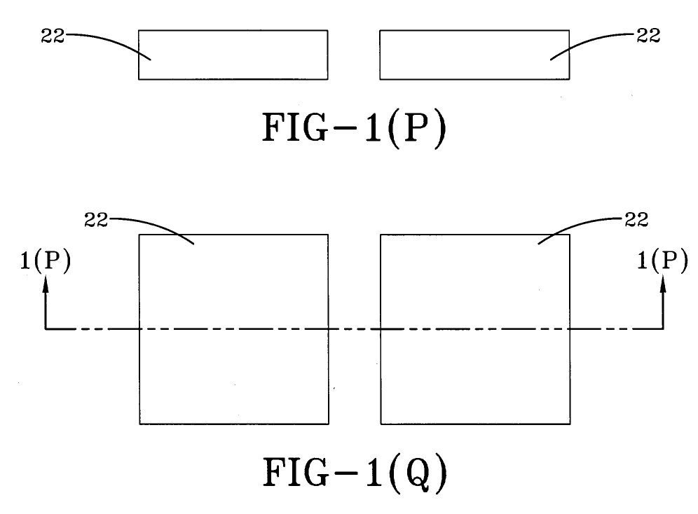

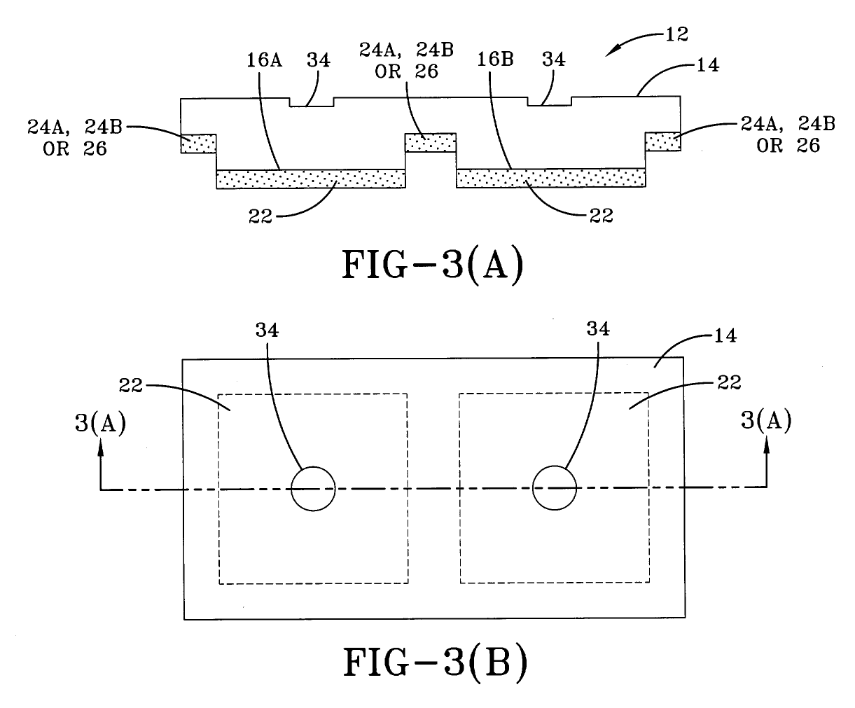

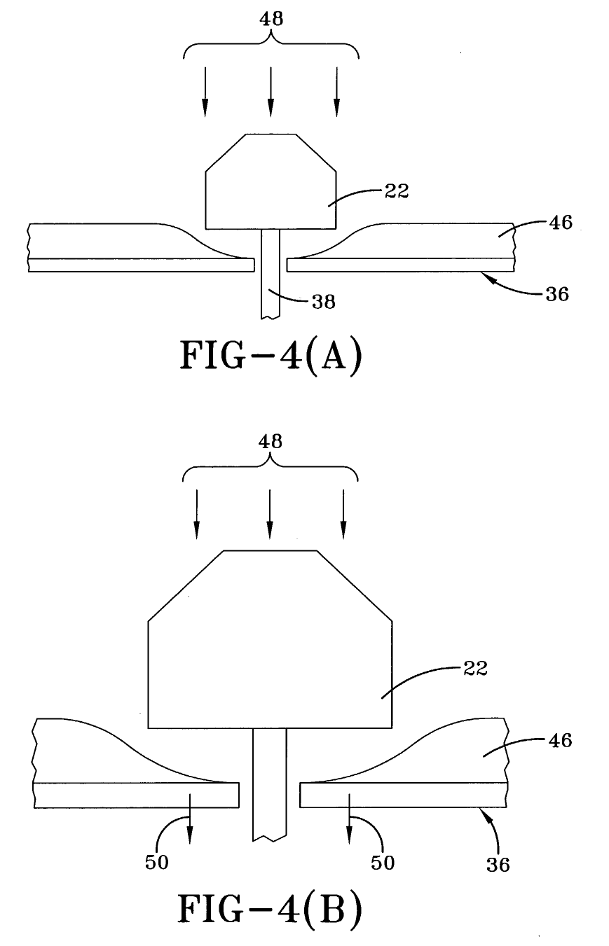

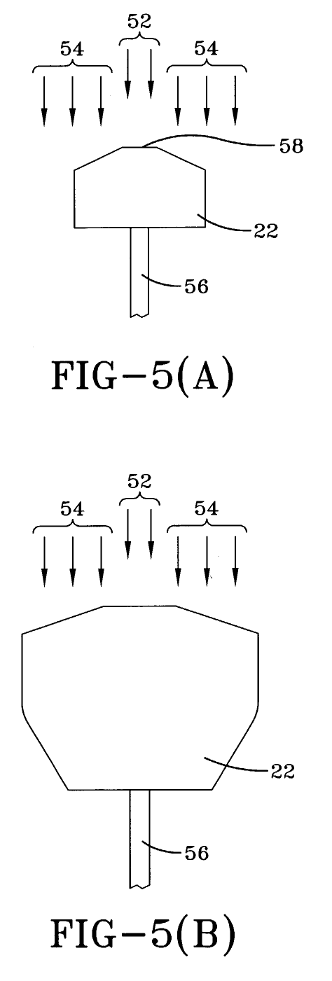

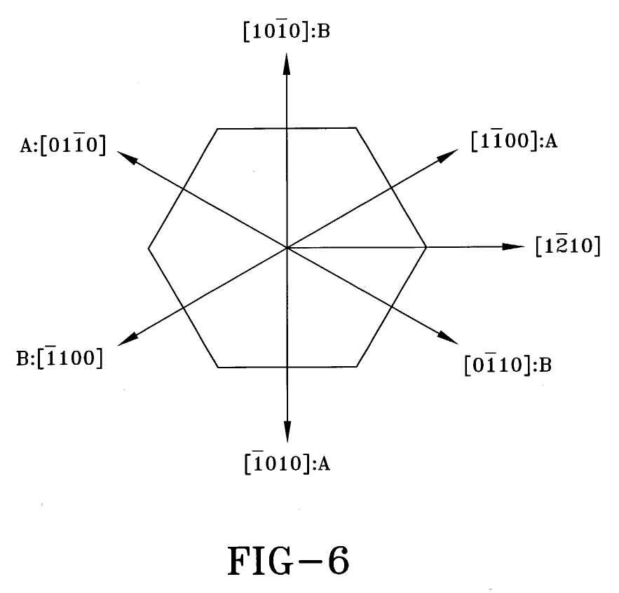

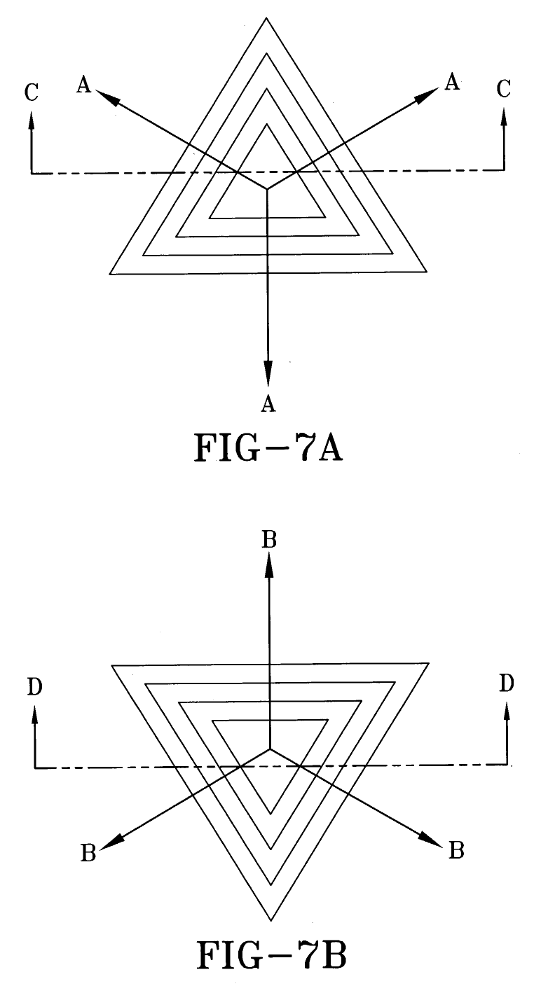

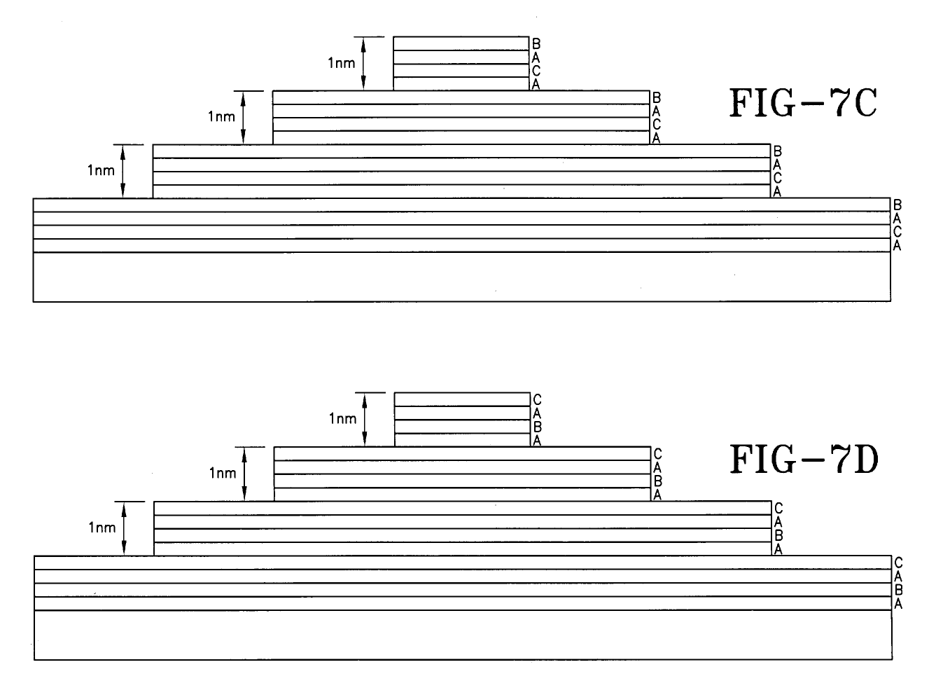

With reference to the drawings wherein the same reference number indicates the same element throughout, there is shown in FIG. 1 composed of FIGS. 1(A), 1(B), 1(C), 1(D), 1(E), 1(F), 1(G), 1(H), 1(I), 1(J), 1(K), 1(L), 1(M), 1(N), 1(P), and 1(Q), FIG. 2, FIG. 3, composed of FIGS. 3(A) and 3(B), FIG. 4, composed of FIGS. 4(A) and 4(B) and FIG. 5, composed of FIGS. 5(A) and 5(B), FIG. 6, and FIG. 7, composed of FIGS. 7(A), 7(B), 7(C), and 7(D), various steps and intermediate results thereof associated with the method of the present invention.

In general, the present invention produces defect-free (or nearly defect-free) single-crystals of relatively large size. The crystals that are produced by the present invention may be directly employed in a fabrication of single-crystal devices, or they can be used as seed crystals for subsequent growth of larger defect-free (or nearly defect-free) single-crystals that can be employed to fabricate single-crystal devices. The methods of the present invention are related to vapor phase growth of relatively large single-crystals free of extended structural crystal defects. Unlike the prior art, discussed in the “Background” section, the methods of the present invention produce a defect-free seed on an atomically-flat crystal that is of different structure and/or material than the seed crystal. Also in contrast to prior art, growth steps for enlargement of the seed crystal are predominantly provided by an edge/corner step nucleation mechanism.

An important feature of the present invention is to select a crystal whose chemical bonding structure is tetrahedral, whose crystal structure is cubic, and which is characterized by having a density of crystal defects that act as sources of growth steps that is low enough that under selected crystal growth conditions homoepitaxial crystal growth takes place on the crystal by step flow growth at steps on the surface of the seed crystal material. The desired growth is produced by a step-flow growth (wherein the steps are initiated by an edge/corner nucleation mechanism) at a rate that is more than the rate of crystal growth due to step flow growth at steps initiated at dislocations.

The first embodiment of the present invention is primarily concerned with the growth of 3C—SiC crystals starting from a 6H—SiC substrate. This embodiment relies on the ability, known in the art, to perform deep and patterned etches of SiC, such as by dry etching as described in the technical article of G. Beheim and C. S. Salupo entitled, “Deep RIE Process for Silicon Carbide Power Electronics and MEMS”, published in Mat. Res. Soc. Symp. Vol. 622, pp. T8.9.1-T8.9.6 (2001).

The first embodiment starts by selecting a 6H—SiC (or 4H—SiC) commercial wafer or 6H—SiC Lely platelet (known in the art) substrate with a planar surface that is prepared and polished by prior art processes; such as that disclosed in U.S. Pat. No. 5,915,194, to within 10 of the (0001) basal plane. Selected patterns of trenches are then etched into this surface in accordance with the teachings of U.S. Pat. Nos. 5,915,194 ('194), 6,165,874 ('874), 6,461,944 ('944) B2 and 6,488,771 ('771), all of which are herein incorporated by reference. These prior art processes yield a patterned mesa, (or an array of mesas) that have a large area atomically-flat top surface that is entirely free of steps and step sources and may be further described with reference to FIG. 1(A).

FIG. 1(A) illustrates a substrate 12, interchangeably referred to herein as a wafer, having a backside 14 and having at least one selected area, but preferably a plurality of selected areas 16A and 16B each serving as a mesa and having boundaries defined by a plurality of trenches 18. More particularly, FIG. 1(A) shows a cross-sectional view of two atomically-flat mesas 16A and 16B, with FIG. 1(B) showing a top view of the substrate 12 of FIG. 1(A). Mesas 16A and 16B have mesa sidewalls 19. Herein, growth on sidewalls of hexagonal SiC mesas is sometimes referred to as a-face growth.

The size of each of the atomically-flat crystal mesas 16A and 16B within the substrate 12 is selected to be relatively large, preferably in excess of 1 mm×1 mm which permits easy handling and mounting of the individual mesas 16A and 16B by themselves in a manner to be further described hereinafter. The depth of the trenches 18 between the mesas 16A and 16B is preferably selected to be relatively deep, at least deeper than the thickness of heteroepitaxial layers grown therein, to be further described, so that the layer being deposited in the trenches 18 does not interfere with the crystal growing from the top surface of the mesas 16A and 16B. More particularly, the depth of the trenches are selected so that the thickness of the layer being grown in the trenches 18 does not rise and come into contact with the interface plane 20 shown in FIG. 1(A). For simplicity, the same interface plane 20 is illustrated for both step-free mesas 16A and 16B in FIG. 1(A), even though each mesa actually has its own step-free interface plane 20 defined by its own step-free planar surface. In particular, the interface planes of various mesas on the same substrate, such as 16A and 16B in FIG. 1(A), are exactly parallel to each other and the (0001) basal plane, but are very slightly vertically offset from each other due to the slight unavoidable tilt angle (less than 1 degree) of the original substrate surface preparation. The initial heteroepitaxial film (e.g., 3C—SiC) is deposited on the substrate 12 comprised of hexagonal polytypes of SiC (e.g., 6H—SiC).

The depositing of the initial heteroepitaxial film is carried out by prior art in accordance with the '771 patent. The process starts with the depositing of a heteroepitaxial film over each of the atomically-flat mesa tops 16A and 16B under controlled conditions. The controlled conditions include controlled nucleation and growth of the initial bilayers of 3C—SiC entirely free of stacking faults and other extended defects. These controlled conditions are preferably those described in the '771 patent.

At this point in the process, a very thin defect-free heteroepitaxial film has been deposited on the mesas by prior art processes. In order to grow the desired size of seed crystal at high growth rates, growth conditions are changed so that the growth mechanism changes to one wherein edge/corner nucleation of new steps (i.e., nucleation of new bilayers) in combination with step flow (of existing steps, i.e., step flow expansion of existing bilayers) growth becomes the dominant growth mechanism. An essential element in this process is that growth takes place on an initial heteroepitaxial film that is defect-free (or nearly defect-free). Growth of the desired product crystal from this point on becomes homoepitaxial growth, in that the thin seed layer 22 is enlarged by further growth of the same material (e.g., 3C—SiC). FIG. 1(C) illustrates the early stage of the growth process, wherein the reference number 22 designates the initial heteroepitaxial film plus some homoepitaxial film growth. During this edge/corner nucleation dominated growth process, the interface plane 20 acts as a border between the two different crystal structures (i.e., between 6H—SiC and 3C—SiC). Below the interface plane 20, homoepitaxial growth of the hexagonal substrate crystal continues. Extending laterally and vertically from the mesa sidewall 19 portions above the interface plane, the cubic crystal structure grows homoepitaxially by the edge/corner nucleation process to form a faceted 3D crystal as shown in FIGS. 1(D) and 1(E). Below the interface plane 20, the faceting behavior of the a-face growth on the 6H—SiC substrate transforms the originally square-shaped substrate into a hexagonal-shaped crystal as shown in FIG. 1(E). Alternatively, the original mesa shape could have been selected to be hexagonal instead of square. Each mesa comprised of a heterofilm on top of a substrate mesa is sometimes referred to herein as a crystal stack.

It is preferred that the step-free top surfaces of the mesas 16A and 16B be selected to be of a shape that is devoid of concave border features. Additionally, the shape of step-free top surface of the mesas 16A and 16B is preferably selected to conform to the preferred growth shape of the second crystal material 22. The mesas 16A and 16B are selected to have a height that exceeds that of the height (i.e., thickness) of the crystal material 22.

Depending on the selected growth conditions, the faceted 3C—SiC seed crystal assumes various shapes; a typical shape is shown in FIGS. 1(D) and 1(E) with facets 40 and 42. The border between the two crystal materials 12 and 22 along the interface plane 20 continues as long as cubic crystal remains defect-free (or nearly defect-free). Another important element in the continued defect-free (or nearly defect-free) nature of the growth is that the growing cubic crystal not merge with (1) extraneous growth 24A from the trenches between mesas, or (2) extraneous growth from elsewhere within the growth chamber.

Normally, deposition also occurs in the trenches 18, so the trenches are made deep enough that the trench deposition 24A preferably does not reach the interface plane 20. An embodiment that reduces (or eliminates) deposition in the trenches 18, generally indicated by reference number 24A, may be further described with reference to FIGS. 1(F) and 1(G).

FIG. 1(F) illustrates a film 24A or 24B deposited in the trenches 18. The trench film 24A is comprised of the polytype 3C, whereas the film 24B is comprised of the same polytype (either 4H or 6H) as the substrate wafer 12. The uncertain composition of the trench film 24A or 24B reflects the fact that we have observed mixing of polytypes in trench regions in our experiments. A top view of the arrangement of FIG. 1(F) is shown in FIG. 1(G).

As previously mentioned, it is important to prevent the film 24A or 24B being grown in the trenches 18 from rising and extending into the 3C/6H interface plane 20. One arrangement for such a prevention, may be further described with reference to FIG. 1(H).

FIG. 1(H) illustrates a growth-inhibiting arrangement 26 placed in the trenches 18 prior to the growth of the crystal 22. The growth-inhibiting arrangement 26 may be selected from the group consisting of a deposited growth-inhibiting film and a guard ring. The growth-inhibiting film in one embodiment can be comprised of a photoresist, which is patterned along the bottom of the trenches 18 and subsequently annealed at a high temperature to form a graphitic carbon. The graphitic carbon 26 inhibits epitaxial growth as demonstrated by E. Eshun, et al, in the technical article entitled “Homo-Epitaxial and Selective Area Growth of 4H and 6H Silicon Carbide Using a Resistively Heated Vertical Reactor”, and published in Materials Research Society Symposia Proceedings, vol. 572, Wide-Bandgap Semiconductors for High Power, High Frequency and High Temperature Applications—1999, of S. C. Binari, A. A. Burk, M. R. Melloch, and C. Nguyen, Eds. Warrandale, Pa.: Materials Research Society, 1999, pp. 173-178.

Further etching and/or deposition of the guard ring, known in the art, may be employed in the trenches 18. However, it should be recognized that any of the growth inhibiting arrangements adds processing steps, which have potential drawbacks.

In one embodiment, the crystal 22 (i.e., the growing seed crystal) is 3C—SiC. The deposition of additional crystal 22 onto the device illustrated in FIG. 1(H) may be further described with reference to FIG. 1(I). For simplicity, the cross-section of crystal 22 is shown schematically as a rectangle in FIG. 1(I), rather than the more complex faceted shape as shown in FIGS. 1(D) and 1(E).

FIG. 1(I) illustrates the additional growth of the crystal 22 on the device with a growth inhibiting arrangement 26 present on the trench 18 bottoms. In particular, it can be seen in FIG. 1(I) that a thicker crystal 22 has been grown while material growth has been prevented in the trenches 18 by the presence of the growth inhibiting arrangement 26. In some embodiments, the growth inhibiting arrangement 26 may be replaced by growth of either of the films 24A or 24B.

Following successful growth of the initial bilayers comprising the heteroepitaxial film 22, which is free of defects, growth conditions are then preferably changed to optimize a thick rapid growth of additional 3C—SiC crystal 22 as desired. Preferred growth conditions for the homoepitaxial growth enlargement of the crystal 22 that favors the edge/corner nucleation with step flow growth are (1) higher precursor concentration and (2) higher growth temperature than that used for the initial heteroepitaxial bilayer growth on the atomically-flat surface. In one embodiment, homoepitaxial growth of additional crystal 22 is carried out for a sufficient period of time that a very thick 3C—SiC crystal 22, on the order of a hundred micrometers, is grown on top of the atomically-flat 6H—SiC mesas 16A and 16B. As detailed in the '771 patent, this epitaxial crystal 22 should be free of extended structural crystal defects (e.g., stacking faults) because it is desired to possess lattice mismatch stress relief (at least partially) along the atomically-flat 3C/6H basal plane interface.

As previously mentioned, it is important that growth coming from the trenches 18 and sidewalls thereof not impede the outward expansion of the growing crystal 22. One way to accomplish this goal is to stop epitaxial growth before the SiC material deposited in the trenches 18 can grow across the 6H—SiC/3C—SiC atomically-flat interface plane 20. For this approach, the polytype of the laterally expanding trench sidewall should preferably be maintained as 6H—SiC film 24B, so that all sidewall growth proceeds laterally (i.e., parallel to the basal plane) instead of vertically (that would cross the interface plane 20). Thus, growth under step-flow conditions is preferred at this stage of the process, as this will best maintain the polytype of the below interface plane portion of the expanding trench sidewall 19 to be 6H—SiC as desired. Step-flow conditions will also assist in maintaining the polytype in the bottom of the trenches 18 to be 6H—SiC, which is desirable because 6H—SiC has been observed in some experimental growth conditions to exhibit a smaller vertical growth rate than 3C—SiC, with the smaller vertical growth rate reducing the possible interference of trench growth 24B with the interface plane 20. It is important to note that proper minimization of the width of trenches 18, between mesas 16A and 16B, (while maintaining large enough width to prevent undesired coalescence of adjacent mesas 16A and 16B) will increase the chances that 6H polytype will be maintained in the trench bottoms, even in spite of the fact that 3C—SiC may be intentionally nucleated on the flat tops of mesas 16A and 16B. The inventors have demonstrated this in their growth experiments.

Contrary to prior art teaching that indicated two-dimensional (2D) nucleation was necessary for continued rapid vertical growth of a 3C—SiC layer, our recent experimental findings show that 3C—SiC still has a desirably high vertical growth rate even when the 2D nucleation rate is reduced to near-zero. In the practice of our invention, we have found that new steps are created on 3C—SiC {111} facets during growth by what appears to be an edge/corner nucleation process, even without 2D nucleation being present. We have also observed that growth under step-flow conditions will promote facet formation on the growing crystal, while growth under high 2D nucleation rate conditions tends to retard the low-order facet formation. We have observed that edge/corner nucelation results in a continuous step train across the {111} 3C—SiC surface flowing inward from the edge of a facet. Thus, desired rapid increase in the thickness of the 3C—SiC epilayer can be accomplished under step-flow growth conditions (i.e., no 2D nucleation). This growth under step-flow conditions (i.e., no 2D nucleation) may also allow the maintenance of the trenches and sidewalls as 6H—sic.

Once growth of sufficiently thick defect-free (or nearly defect-free) 3C—SiC homoepitaxial crystal 22 has been accomplished on top of the atomically-flat mesas 16A and 16B, the wafer could be oxidized to optically reveal which mesas 16A and 16B have 3C—SiC homoepitaxial crystal 22 that contain extended structural crystal defects and which mesas are free of extended structural crystal defects. One such procedure for optical revealing is described by J. A. Powell et al in the technical article entitled, “Application of Oxidation to the Structural Characterization of SiC Epitaxial Films,” Appl. Phys. Lett., vol. 59, no.2, pp. 183-185, 1991. Other methods, known in the art, to reveal defects could be employed, as long as the integrity and cleanliness of the crystal remains adequate for homoepitaxial crystal growth following the application of appropriate defect detection techniques.

After the desired thick crystal 22 is formed as shown in FIG. 1(I), the device of FIG. 1(I), sometimes referred to as a wafer, can then be separated into individual mesa seed crystals 16A and 16B by physical methods that do not damage the defect-free (or nearly defect-free) seed regions. These steps should suitably prepare and separate each mesa for subsequent individual mounting for carrying out bulk growth to be further described hereinafter. The separation of the individual mesas 16A and 16B may be further described with reference to FIG. 1(J) and FIG. 1(K), wherein FIG. 1(J) shows a cross-section of the wafer of FIG. 1(K), where FIG. 1(K) is a backside view of the wafer with the position of mesa borders on the wafer topside denoted by dotted lines. FIG. 1(J) is similar to the device shown in FIG. 1(I) in most respects, with the only substantive differences being: (1) the trench regions are generalized as having either a homoepitaxial 6H—SiC growth 24B, heteroepitaxial 3C—SiC growth 24A, or growth inhibiting arrangement 26 discussed previously, and (2) the device is flipped upside down (so that mesas 16 on the wafer topside now face toward the bottom of the figure) to reflect the majority of embodiments for achieving separation and isolation of individual mesas, to be further described, that rely on altering or removing the backside 14 of the wafer substrate 12.

The separation of the individual mesas 16A and 16B can be accomplished with patterned dry etching of the wafer from either the frontside or the backside, with the backside arrangement shown in FIG. 1(J) having a backside view thereof as shown in FIG. 1(K). One simple process involves unpatterned etching or lapping of the backside. In one embodiment, depicted by the cross-section of FIG. 1(L), the wafer is greatly thinned by backside lapping and/or etching so that only very thin regions of substrate crystal 12 remain underneath the trenches 18. At this point mesas could be separated by cleaving or fracturing the wafer to break along the trenches 18 where the crystal 12 is thinnest. In another embodiment, the wafer is thinned until the trenches 18 are reached. Either of these separation embodiments can separate the wafer into numerous 3C—SiC/6H—SiC crystal stacks, that are comprised of a layered structure of substrate remnant 12 and crystal 22, as shown in FIG. 1(N) with the backside of the 6H—SiC crystal stacks shown in FIG. 1(M).

In order to ensure that there are no undesirable interactions of 3C—SiC and 6H—SiC in a subsequent bulk growth, the etching or lapping can be continued until the entire 6H—SiC layer is removed, leaving behind a defect-free (or nearly defect-free) 3C—SiC seed crystal for subsequent bulk growth as shown in cross-section in FIG. 1(P) with the 3C—SiC crystal 22 also being shown in top view in FIG. 1(Q).

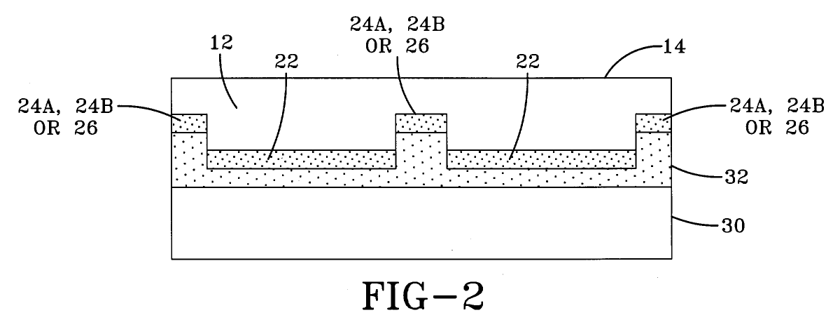

Preferably, the wafer 12 of FIG. 1(J) can be mounted (prior to carrying out the above-discussed backside lapping and/or polishing) as shown in FIG. 2 and bonded with its topside (containing grown crystal 22) facing down and onto a carrier wafer 30 and mounted thereto by means of a mounting compound 32 selected from the group consisting of Crystal-bond, a wax, photoresist, or some other comparable meltable and/or dissolvable wafer mounting compound, known in the art.

If desired, the backside 14 of the substrate 12 can be polished and prepared for photolithography prior to or after its mating with the carrier wafer 30. Patterned etching of the backside to facilitate a simple “post hole” may be accomplished or other appropriate structure may be implemented that is beneficial for subsequent mounting of the crystal seeds comprised of crystal 22. The forming of the post holes may be described with reference to FIG. 3 composed of FIGS. 3(A) and 3(B).

FIG. 3(A) illustrates a cross-section of the wafer 12 of FIG. 1(J) backside up and after etching that produces post holes 34 used for mounting purposes. FIG. 3(B) is a backside view of the wafer 12 of FIG. 3(A).

The depth of a backside post holes 34 of FIGS. 3(A) and 3(B) should preferably be about half the thickness of the crystal stack (either all 3C—SiC crystal 22 or 3C—SiC/6H—SiC combination comprised of the 3C—SiC crystal layer 22 and remnant of 6H—SiC wafer 12), left at the end of the process. Preferably, a pattern is selected so that patterned etching produces a hole cavity in the crystal stack bottomside having a depth less than 80% of the height (i.e., thickness) of the crystal stack. Further, it is preferred that patterned etching be selected to produce a hole cavity in the crystal stack bottomside that does not penetrate the interface plane 20. During the process, the backside etch mask can be stripped, and the wafer 12 etched to separate the individual seeds, that is, mesas 16A and 16B. The mounting compound 32 (not shown in FIG. 3, but shown in FIG. 2) could then be removed, and the separated crystals without defects identified using one of the defect delineation techniques previously described. One or more suitable crystal stacks, with crystal 22 exhibiting the fewest defects, can then be separated and selected for subsequent bulk growth.

Once separated, the seed crystals, shown in cross-section in FIGS. 1(N) or 1(P), can be suitably mounted in a suitable crystal vapor transport growth system to carry out enlargement of the seed crystal into a much larger size “bulk” crystal. The resulting bulk crystals could themselves be suitably divided, for use as wafers for device fabrication, or as seeds for growth and mass production of additional crystals and wafers.

An additional method for reducing the chance of the growing bulk crystal 22 coalescing with other material is illustrated in FIG. 4 composed of FIGS. 4A and 4B. In this method, a movable baffle 36 is included with crystal support structure 38 to inhibit coalescence with material 46 that may be growing on the support structure 38. FIG. 4(A) illustrates a side view of the growing bulk crystal 22 and of material deposition 46 on the movable baffle 36 as the growing bulk crystal 22 is subjected to gas flow 48. The mounting of the crystal 22 to support structure 38 is preferably facilitated by backside hole 34 shown in FIG. 3. The operating principle of this method is that the spacing between the baffle (including unwanted material 46 growing on the baffle 36) is kept small enough to reduce precursor material from diffusing into the gap between the growing crystal 22 and the movable baffle 36. Hence, growth is prevented from taking place on the growing crystal 22 in the vicinity of the support structure 38. FIG. 4(B) illustrates that as additional growth 46 occurs on the baffle 36, the baffle 36 is moved away (as shown by directional arrows 50) from the growing crystal 22 so that the growth 46 on the baffle 36 does not coalesce with the growth on the growing crystal 22. By properly selecting the baffle material and controlling the temperature and other conditions of the baffle 36, the growth on the baffle can be reduced or eliminated.

Another method for reducing the chance of the growing crystal coalescing with other material is illustrated in FIG. 5 composed of FIGS. 5(A) and 5(B). In this method, the concentration of the precursor is not uniform in the input gases shown in FIG. 5 as comprising gas flows 52 and 54. More particularly, the concentration of the precursor is minimized at the vicinity of a support structure 56 shown in FIG. 5. FIG. 5(A) illustrates two gas flows 52 and 54 directed toward the growing bulk crystal 22 that is supported on a support structure 56, whereby gas flow 52 contains a carrier gas and precursors for the growth of the crystal 22 and gas flow 54 contains only the carrier gas. In another embodiment, second gas flow 54 may contain crystal growth precursor, but at a reduced concentration or flow rate than first gas flow 52. The precursors are preferably gases that are silane and a hydrocarbon encouraging the growth of silicon carbide. From FIG. 5(A) it should be seen that gas flow 52 is directed onto the growing crystal at a location 58 furthest from the support structure 56 as compared to the gas flows 54. This forces atoms to migrate a great distance (and over facet edges) in order to reach the vicinity of the support structure 56. The growth rate in the vicinity of the support structure 56 will be less, hence, lessening the chance for growth that could undesirably coalesce with growth on the support structure 56. FIG. 5(B) illustrates the growing bulk crystal 22 further along in the growth process from that of FIG. 5(A).

With suitable mounting that permits unencumbered lateral and vertical expansion (i.e., growth) of the crystal and a suitable growth system, known in the art, that suitably controls the temperature of the crystal and suitably delivers growth reactants to the crystal surfaces, it should be possible to produce very large 3C—SiC crystals free (or nearly free) of structural crystal defects. It is well known to those skilled in the art that suitable mounting of the seed crystal so as to prevent stress and resulting dislocations during the crystal enlargement process is crucial. Thus, as known in the art, choice of seed crystal mounting materials, geometry, and procedures are critical to maintaining low stress and low thermal gradients during crystal growth.

It is also well known (Gorin and Ivanova) that a cubic crystal structure (such as 3C—SiC) will exhibit growth facets under certain conditions. We have observed <111> facets in the practice of our invention, to the degree that most of a tetrahedral pyramid, (i.e., a three-sided pyramid with a small flat top instead of a top vertex) was formed after a thick 3C—SiC heteroepitaxial film 22 was grown on a small 6H—SiC mesas 16A and 16B. A typical faceted crystal is schematically shown in FIGS. 1(D) and 1(E). By selecting an equilateral triangular shape of the 6H—SiC seed mesas 16A and 16B, 3C—SiC crystal 22 tetrahedra can be produced with a combination of the processes. By adjusting the growth conditions to promote or inhibit 2D nucleation, we have observed in the practice of our invention that facet formation can be promoted or inhibited to influence the shape of the growing crystal.

Based on the foregoing detailed descriptions, the essential elements of the embodiment of the present invention that provides for the vapor phase crystal growth of one or more defect-free (or nearly defect-free) seed crystals of a selected cubic crystal material on a substrate crystal surface wherein the desired seed crystal material is different than the substrate crystal material, comprises the steps of:

(a) selecting a substrate crystal material whose chemical bonding structure is tetrahedral, and which is characterized by exhibiting a behavior that a step-free planar surface is produced on a selected planar surface of the substrate crystal, wherein the selected planar surfaces have a crystallographic orientation that is within 10 of a basal plane orientation of the selected substrate and, wherein the step-free surface is produced under selected crystal growth conditions;

(b) selecting a desired cubic seed crystal material whose chemical bonding structure is tetrahedral and is characterized by exhibiting the behavior that (1) under a first set of selected growth conditions single-island heteroepitaxial crystal growth is obtained having a sequence of bilayers of the seed crystal material on selected step-free surfaces of the selected substrate crystal material and (2) under a second set of selected crystal growth conditions subsequently homoepitaxial crystal growth of additional desired seed crystal material on the desired seed crystal material is obtained by having step flow growth occurring at steps on the surfaces of the desired cubic seed crystal material initiated by an edge/corner nucleation mechanism yielding homoepitaxial crystal growth at a rate that is more than a rate of crystal growth due to step flow growth at steps on the surfaces of the desired cubic seed crystal material initiated at defects in the desired cubic seed crystal material,

(c) preparing at least one step-free top surface on the selected substrate crystal material, wherein the at least one step-free top surface is of selected shape and selected crystallographic surface orientation that defines at least one step-free interface plane,

(d) initiating single-island heteroepitaxial crystal growth of bilayers of the desired cubic seed crystal material on top of said at least one step-free interface plane of the selected substrate crystal,

(e) continuing homoepitaxial crystal growth of additional cubic seed crystal material above said interface plane under said second set of selected crystal growth conditions that yields homoepitaxial crystal growth of seed crystal material by step flow growth at steps produced by an edge/corner nucleation mechanism at the rate that is more than the rate of crystal growth due to step flow growth at steps produced by said defects, and

(f) continuing homoepitaxial seed crystal growth in a selected manner that the seed crystal growth occurs without impedance or convergence from other solid materials until a desired seed crystal shape and height are achieved forming at least one first selected single seed crystal, herein defined to be a first selected seed crystal stack.

In the practice of the invention, it is preferred that an analysis be performed on the desired cubic crystal material that may reveal crystal defects therein. Based upon inspection of the results produced by the analysis, crystal stacks that have the lowest defect density can be selected and subdivided off for further growth enlargement. The performed analysis may be selected from the group of treatments comprising: a thermal oxidation technique, a defect-preferential chemical etch, an X-ray analysis technique, and a surface profilometry technique, all known in the art.

Further, in the practice of the present invention, desired crystal stacks are provided by physically isolating selected crystal stacks which is accomplished by using a process selected from the group comprising: cutting with a dicing saw, patterned dry etching, non-patterned dry etching, patterned wet etching, non-patterned wet etching, laser-based cutting cleaving, mechanical lapping, and patterned application of a growth-inhibiting material, all known in the art.

Still further, in the practice of the invention for all embodiments thereof, the selected growth conditions comprise a set of growth parameters comprising at least crystal temperature, reactor pressure used for the deposition, concentration of reactor precursors for material being deposited, concentration gradients of the reactor precursors, composition of carrier gas used in the reactor, and flow rate of carrier gas within the reactor. Further, it is preferred that the selected growth conditions be provided by a growth process selected from the group consisting of chemical vapor deposition, physical vapor phase epitaxy, and sublimation processes. More particularly, it is preferred that the growth process be provided by chemical vapor deposition that is carried out using precursor gases consisting of silane and a hydrocarbon for the growth of silicon carbide, wherein the seed crystal material is 3C—SiC. In addition, the growth conditions for crystal growth include a temperature in the range of 1000° C. to 2000° C.

Other embodiments of the present invention provide for the separation of one or more selected seed crystal stacks from the substrate crystal and remounted in a manner wherein each crystal stack can be used as a seed crystal for the growth of a bulk crystal.

The essential elements of another embodiment of the present invention that provides for the vapor phase crystal growth of a relatively large single crystal of a selected cubic crystal material starting from a selected seed crystal of the same crystal material, comprises the steps of:

(a) selecting a seed crystal material whose chemical bonding structure is tetrahedral, whose crystal structure is cubic, and which is characterized by having a sufficiently low density of crystal defects that can initiate growth steps that under a first set of selected crystal growth conditions homoepitaxial crystal growth takes place on the seed crystal material by step flow growth at steps on the surface of the selected seed crystal material initiated by an edge/corner nucleation mechanism at a rate that is more than a rate of crystal growth due to step flow growth at steps on the surface of the selected seed crystal material initiated at defects in the selected seed crystal material,

(b) supporting the selected seed crystal material with a selected support structure in a manner that during subsequent crystal growth under selected growth conditions, crystal growth occurs without impedance or convergence of the growing crystal with any solid material that is external to said growing crystal,

(c) initiating crystal growth of crystal material on the selected seed crystal material under said first set of selected crystal growth conditions that yields homoepitaxial crystal growth of low-defect crystal material by step flow growth at steps on the surface of the selected seed crystal initiated by said edge/corner nucleation mechanism at said rate that is more than said rate of crystal growth due to step flow growth at steps on the surface of the said selected seed crystal initiated at defects in the said selected seed crystal,

(d) continuing the homoepitaxial crystal growth of the crystal material in a selected manner so that the crystal growth occurs without impedance or convergence of the growing said crystal with solid materials external to said growing crystal until the desired shape and height of the single crystal is achieved forming at least one large low-defect crystal of the said selected crystal material.

Conditions can be created wherein the desired growth of the embodiments of the present invention takes place by (1) 2D nucleation, plus step flow, or (2) edge/corner nucleation, plus step flow. For a given super saturation, edge/corner nucleation, plus step flow will require a higher temperature. This is needed because higher surface diffusion rate of atoms is desired to initiate edge/corner nucleation, plus step flow.

The practice of the present invention, which is particularly related to the formation of low-defect seed crystals and the growth of low-defect bulk crystals, is based on our discovery that under specific growth conditions, low-defect three-dimensional (3D) faceted seed crystals of 3C—SiC crystals can be grown at high growth rates on atomically-flat hexagonal SiC surfaces. We further discovered that the 3D growth was primarily due to an edge/corner nucleation process in combination with step flow growth rather than a 2D nucleation process followed by step flow growth as proposed in U.S. patent '194. We further discovered that, under specific growth conditions, continued growth of the low-defect seed crystals can be carried out at the high growth rates provided the growing 3D crystal was prevented from coalescing with any extraneous growth on either the support structure of the growing crystal or any surrounding surfaces within the growth system.

In general, the invention provides methods for the vapor phase growth of semiconductor bulk single crystals, and more particularly, a method for producing low-defect bulk crystals of cubic silicon carbide (3C—SiC), cubic aluminum nitride (AlN), cubic gallium nitride (GaN), and other materials or compounds. Specifically, the invention enables the growth of desired low-defect cubic seed crystals on atomically-flat hexagonal crystal surfaces. Additionally, the invention enables the growth of low-defect bulk cubic single crystal starting from any low-defect cubic seed crystal.

The practice of our invention can be used to grow relatively large crystals of non-SiC materials free (or nearly free) of structural crystal defects. For example, with suitable modifications in heteroepilayer nucleation 20 and growth conditions, the method hereinbefore described with reference to FIG. 1, is suitable for growing defect-free diamond crystals starting from atomically-flat 6H—SiC or 4H—SiC mesas 16A and 16B of FIG. 1(A). In general, the process is suited for heterogrowth of materials with cubic crystal structure. Our observations show that cubic crystals with their four (4) equivalent basal planes can be propagated in all three dimensions, even in step-flow growth conditions where two-dimensional (2D) island nucleation and dislocation assisted growth have been completely eliminated.

In the practice of our invention, dislocation assisted growth needs to be taken into account in some of the growth processes. For example, a dislocation can be formed part way through the growth. Impurity inclusions are well known by those skilled in the art to nucleate dislocations during crystal growth. Such dislocations initiate new growth steps and impact subsequent crystal shape and quality. Even with some dislocations present, the material produced by this invention is far superior than material produced by prior art processes.

It is known to those skilled in the art that the polar basal plane “Si-face” and “C-face” of hexagonal and rhombohedral SiC crystals exhibit different growth and nucleation properties. An examination of the crystal structure of 3C—SiC yielded by the practice of the present invention reveals that the tetrahedron consisting of the four {111} basal plane facets of 3C—SiC would all consist of the same face polarity. For the case of a tetrahedral pyramid grown starting from an atomically-flat Si-face 6H—SiC mesas 16A and 16B, the three {111} side facets would be C-faces. If the pyramid was incomplete with a flat top, the flat-topped surface is a Si-face. Because these Si faces have different nucleation and growth properties, it is possible to influence the shape of the crystal by varying the growth conditions at various stages of Si-face facet formation versus C-face facet formation.

It is well known in the art that two rotational twin variants of 3C—SiC can 2D nucleate on the (0001) plane of hexagonal SiC. One twin variant, herein referred to as 3C(I), has the stacking ABCABC., while the other twin variant, hereafter referred to as 3C(II), has the stacking ACBACB. When {111} facets are formed during 3D growth, both 3C(I) and 3C(II) will grow toward tetrahedral pyramid shapes, wherein each face (including the bottom) of the ideal tetrahedral pyramid is an equilateral triangle formed by a {111} growth surface. However, the triangular-shaped bases (i.e., the bottom faces) of the tetrahedral pyramids produced by 3C(I) and 3C(II) will be rotated from each other by 180 degrees, reflecting the opposite twin symmetry of the two crystal structures with respect to each other and the underlying hexagonal substrate stacking.

It is also important to note that the stacking sequence for both 4H—SiC and 6H—SiC contain sub-stacking for both 3C(I) and 3C(II) variants. For example, the stacking of 6H—SiC is ABCACBABCACB, which is three layers of 3C(I)(i.e., ABC) followed by three layers of 3C(II)(i.e., ACB). Similarly, the sub-stacking for either 3C(I) or 3C(II) can be extracted from the 4H—SiC stacking sequence. As taught in the '194 patent when 3C—SiC 2D nucleates on a (0001) plane of hexagonal SiC, the variant that nucleates is determined by the stacking sequence of the topmost (or last) two bilayers. When the topmost stacking of a hexagonal mesa ends with AB (with B the topmost bilayer), the rotational variant of 3C—SiC that nucleates will be ABC (i.e., 3C(I)). When the topmost stacking of a hexagonal polytype mesa ends with AC (with C the topmost bilayer), the rotational variant of 3C—SiC that nucleates will be ACB (i.e., 3C(II)).

The ability to produce an array of 3C tetrahedral pyramids which all have the same rotational variant has benefits for the practice of the present invention. Tetrahedrally-shaped 3C—SiC crystals, all with the same rotational orientation, could be grown on step-free mesas if the initial step-free surface of each mesa is shaped like an equilateral, or nearly equilateral, triangle with sides of each triangle selected perpendicular to the same set of three of the six equivalent <1100> directions of the hexagonal (first) crystal substrate material. If this condition is satisfied, then the growth of the same 3C variant on each mesa is favored in subsequent growth.

The teachings of U.S. patents '194 and '771 demonstrate that when 3C—SiC is heteroepitaxially 2D-nucleated on a hexagonal (either 4H—SiC or 6H—SiC) (0001) basal plane surface, the nucleated 3C layer acquires the cubic stacking of the underlying top two bilayers of the alphα-SiC surface. However, none of this prior art discloses a method or process for selecting which of the two rotational variants will actually form when heteroepitaxy is carried out on a step-free surface. This is because the '194 process, as well as that of U.S. patent '771 makes no disclosure of how to prepare the hexagonal substrate so that the stacking sequence termination of each step-free mesa surface is predetermined instead of random.

The teachings of '194 patent indicate that in order to select which rotational variant of 3C—SiC nucleates, advantageous to the present invention, the stacking sequence termination of the underlying step-free hexagonal-polytype mesa surface must become predetermined instead of random. In U.S. patent '771, the stacking sequence of the heteroepitaxial film on a given mesa is fixed by the stacking sequence of the topmost two bilayers of that particular substrate mesa at the initiation of step c in claim 1. For example, if the topmost bilayers of the hexagonal polytype step-free surface terminate with ABC stacking (with C being the topmost bilayer), then the 3C layer nucleated will be 3C(I) (i.e., will continue the ABC stacking).

Therefore, if the stacking sequence of the topmost bilayers of the hexagonal (first) crystal substrate material can be selected for all mesas, the rotational variant of 3C—SiC that nucleates could be selected for all the mesas on the substrate, which would have clear benefits with respect to the present invention. For example, predictable seed crystal shapes could be selected with predetermined facets and rotational orientation relative to the substrate. Such a mesa surface would necessarily have to be step-free, or have well-defined steps of c-axis repeat distance for a given polytype, so that regardless of where the topmost bilayer resided within a particular pregrowth mesa, the stacking sequence of the top two bilayers would be identical. The step-free surface with predetermined stacking surface termination is ideal because it enables the combined practicing of the full benefits of the '194 and '771 patents, and thus much higher quality 3C—SiC material to be grown than occurs for nucleation on a stepped surface.

Related U.S. patent application Ser. No. 10/198,668 discloses methods, related to the present invention, for producing nanometer scale step heights. In some embodiments, U.S. patent application Ser. No. 10/198,668 produces steps of unit-cell repeat height on growth mesas. In such cases where “staircases” of unit-cell repeat height have been constructed, the stacking sequence termination of each terrace in the staircase will be the same. Of particular interest to the present invention is the embodiment depicted in FIGS. 6 and 7 of U.S. patent application Ser. No. 10/198,668, wherein in FIG. 7A thereof teaches the steps perpendicular to the <1\overline{1}00> directions of the square mesa are unit-cell height (i.e. 1 nm, or 4 bilayers for the depicted 4H—SiC example) forming staircases on two sides of the depicted mesa. However, it should be noted (perhaps more evidently in FIG. 7C of Ser. No. 10/198,668) that the terraces on the top {1\overline{1}00} side of FIG. 7A of this teaching are two bilayers (i.e. 0.5 nm, or one half of the 4H—SiC unit repeat height) displaced in the stacking sequence from the terraces on the bottom {1\overline{1}00} side of FIG. 7A of this teaching. Thus, if the stacking sequence of the top bilayers on the top side of FIG. 7A of this teaching corresponded to 3C(I) stacking sequence termination, the stacking sequence of the top bilayers on the bottom side of FIG. 7A of U.S. patent application Ser. No. 10/198,668 would correspond to 3C(II) stacking sequence termination.

FIG. 6 disclosed herein, depicts the hexagonal crystal structure unit cell and the Miller indicies (known in the art) for the six equivalent <1\overline{1}00> directions of the hexagonal polytypes of silicon carbide. A more complete discussion of these directions and indicies is given in Chapter 11 (pages 257-293) entitled “Growth and Characterization of Silicon Carbide Polytypes for Electronic Applications” by Powell et al. of the technical book entitled “Semiconductor Interfaces, Microstructures and Devices: Properties and Applications” edited by Zhe Chuan Feng and published by Institute of Physics Publishing, Bristol and Philadelphia, 1993. In FIG. 6, disclosed herein, three of these directions have been denoted by an A designation, while the remaining three directions have been designated by a B designation. The angle (i.e., angular separation) between each A designated direction is 120 degrees, while the angular separation between each B designated direction is also 120 degrees. The angular separation between any given A direction and its two closest (adjacent) B directions is 60 degrees. The importance of the A set of <1100> directions with angular separation of 120 degrees and the B set of <1100> directions with angular separation of 120 degrees will be further described with reference to FIG. 7.

If one were to apply the process depicted in FIGS. 6 and 7 of U.S. patent application Ser. No. 10/198,668 to a mesa with a nearly equilateral triangular shape, wherein all three sides of the mesa were oriented nearly perpendicular to the same set (either set A or set B as shown in FIG. 6 of this invention) of three of the six <1\overline{1}00> directions, a stepped pyramid of consisting of stacked concentric triangles would be produced. The selection of this properly oriented triangle mesa shape enables, after the application of one of the processes disclosed in U.S. patent application Ser. No. 10/198,668, all terrace surfaces (including the topmost bilayers of the pyramid) formed by this stack of concentric triangles to be terminated by the same stacking sequence (either ABC 3C(I) or ACB=3C(II)). Thus, one new aspect of the present invention is that the orientation of a given triangular substrate mesa relative to one of the two sets of <1100> crystallographic directions determines which stacking sequence (ABC or ACB) that terminates the top surfaces after applying the prior art process of U.S. patent application Ser. No. 10/198,668.

FIG. 7 disclosed herein for this invention illustrates the step/terrace pattern that would be produced by applying the process disclosed in U.S. patent application Ser. No. 10/198,668 to two appropriately oriented triangular shaped mesas. The two mesas (following application of the disclosed in U.S. patent application Ser. No. 10/198,668 process) are further illustrated in FIG. 7 of this invention. FIG. 7A shows the top view of steps produced on a triangular mesa with sides oriented perpendicular to the A set of <1\overline{1}00> crystallographic directions with 120 degrees angular separation illustrated in FIG. 6, while FIG. 7B shows a top view of steps produced on a triangular mesa with sides oriented perpendicular to the B set of <1\overline{1}00> of crystallographic directions with 120 degrees angular separation illustrated in FIG. 6. FIG. 7C shows a cross-section of the steps produced on the mesa depicted in FIG. 7A. The step heights are equal to the repeat height for the particular polytype of the substrate (e.g. 1 nm for 4H—SiC). Hence, the mesa of FIGS. 7A and 7C will have plateaus terminated with an AB stacking sequence as illustrated in FIG. 7C. FIG. 7D shows a cross-section of the steps produced on the mesa depicted in FIG. 7B, illustrating that the mesa of FIGS. 7B and 7D will have plateaus terminated with an AC stacking sequence.

Once the surface illustrated in FIG. 7 with selected topmost stacking sequence is achieved, the steps can be grown out of existence by homoepitaxial growth to form an atomically-flat mesa surface, similar to the teachings of the '194 patent, yet with selected topmost stacking sequence, instead of random topmost stacking sequence, having been achieved. Thus, when heteroepitaxial nucleation of 3C—SiC is subsequently initiated on this step-free surface via the further teachings of the '194 patent and disclosed in U.S. patent '771 the rotational variant of 3C—SiC that grows has become selected, instead of random as with prior art. The result is that by appropriately orienting all triangular mesas within an array such that the sides of the triangular mesas are perpendicular to the same set of <1\overline{1}00> directions with angular separation of 120 degrees (either the A set or the B set illustrated in FIG. 6 herein), the process of this invention can be selected to produce an array of mesas with 3C—SiC grown on top whereby all of the 3C—SiC crystal growth is of selected variant.

To those skilled in the art, many processes can be applied to an array of 3C—SiC mesas of selected (rather than random) variant to advantageously fabricate improved semiconductor devices. In some cases, it may be beneficial to select all the mesas on a given substrate oriented to the A set of <1\overline{1}00> directions with angular separation of 120 degrees, so that all 3C—SiC crystals grown on the substrate have the same rotational variant. Similarly, it may also be advantageous to select patterns of both rotations of 3C—SiC mesas to reside in selected areas of a given hexagonal polytype substrate wafer. The ability to select the rotation of 3C—SiC grown on each mesa has benefits that will immediately suggest themselves to those skilled in the art. The ability to predetermine the stacking sequence termination of a mesa and subsequent rotational variant of 3C—SiC that grows has not, to the best of our knowledge, been taught or demonstrated in the prior art.

It should now be appreciated that the hereinbefore described methods and minor variations thereof are capable of producing relatively large single crystals free (or nearly free) of extended structural crystal defects not possible with prior art. Unlike prior art, these methods of the present invention produce a defect-free (or nearly defect-free) single crystal on an atomically-flat surface of a crystal substrate that is not of the same structure or material as the produced large single crystal. Also unlike prior art, the growing crystal is not subjected to large stresses induced by either the seed crystal or the crystal growth apparatus. This invention enables, for the first time, defect-free (or nearly defect-free) bulk crystals of 3C—SiC to be produced in a reproducible fashion. This invention leads to enabling the mass production of 3C—SiC bulk crystals and wafers of far superior crystal quality to commercially available SiC wafers, which are presently offered only in the non-cubic polytypes of SiC.

It should be further appreciated that minor variations of this invention enables attainment of large, reproducible (i.e., mass-producible), high quality (free or nearly free of extended structural defects), bulk crystals of GaN, AlN, diamond, and other challenging single-crystal semiconductor substrate materials that were not practically attainable with prior art. For growth of materials with cubic crystal structure, the methods of the present invention make use of an edge/corner nucleation process for the rapid growth of the crystal. The relative absence of dislocation-based step sources and two-dimensional (2D) island nucleation enable the observation of the edge/corner nucleation mechanism. Three-dimensional (3D) structures, such as tetrahederal pyramids and corner cube arrays that are sometimes useful for retroreflection, can be grown with the practice of this invention. Fabrication of V-groove vertical SiC MOSFET's may also be obtained. The invention enables the fabrication of superior 3C—SiC semiconductor devices. Similarly, improved crystal quality enables improvement to the performance and reliability of III-N and diamond semiconductor devices.

The invention has been described with reference to preferred embodiments and alternates thereof. It is believed that many modifications and alterations to the embodiments as discussed herein will readily suggest themselves to those skilled in the art upon reading and understanding the detailed description of the invention. It is intended to include all such modifications and alterations insofar as they come within the scope of the present invention.

What we claim is:

1. A method for the vapor phase crystal growth of one or more single crystals of a selected second crystal material starting with a selected first crystal, wherein said first crystal material is different than said second crystal material, and wherein said method comprises the steps of:
(a) selecting said first crystal material whose chemical bonding structure is tetrahedral, and said first crystal material being characterized by exhibiting a behavior that a step-free basal plane surface is produced on a selected planar surface of said first crystal material, wherein said selected planar surfaces have a crystallographic orientation that is within one (1) degree of a basal plane orientation of said first crystal material, and wherein said step-free surface can be produced under selected crystal growth conditions;
(b) selecting said second crystal material whose chemical bonding structure is tetrahedral and whose crystal structure is cubic, and is characterized by exhibiting the behavior that (1) under a first set of selected growth conditions said second crystal material exhibits single-island heteroepitaxial crystal growth which is obtained having a sequence of bilayers of said second crystal material on selected step-free surfaces of said selected first crystal and (2) under a second set of selected crystal growth conditions said second crystal material subsequently exhibits homoepitaxial crystal growth of additional said second crystal material on said second crystal material by having step flow growth occurring at steps on the surfaces of said second crystal material initiated by an edge/corner nucleation mechanism at a rate that is more than a rate of crystal growth due to step flow growth at steps on the surfaces of said second crystal material initiated at defects in the second crystal material,
(c) preparing at least one step-free top surface on said selected first crystal, wherein said at least one step-free top surface is of selected shape and selected crystallographic surface orientation that defines at least one step free interface plane,
(d) initiating single-island heteroepitaxial crystal growth of bilayers of said second crystal material on top of said at least one step-free interface plane of said first crystal,
(e) continuing crystal growth by said homoepitaxial crystal growth of additional said second crystal material above said interface plane under said second set of selected crystal growth conditions that yields homoepitaxial crystal growth of said second crystal material by step flow growth at steps initiated by an edge/corner nucleation mechanism at said rate that is more than said rate of crystal growth due to step flow growth at steps initiated at said defects, and
(f) continuing said homoepitaxial crystal growth of said second crystal material in a selected manner so that said crystal growth occurs without impedance or convergence from other solid materials until desired said second crystal material crystal shape and height are achieved forming at least one first selected crystal stack.

2. The method according to claim 1, wherein said selected first crystal has a wafer-like shape with a selected topside defined as the side of said selected crystal wafer on which said second crystal material is deposited, and wherein an opposite side of said selected crystal wafer is defined as being the bottomside.

3. The method according to claim 2, wherein said at least one step-free top surface is comprised of an array of separated step-free top surfaces produced on top of mesas each with a selected shape, orientation, and mesa height formed by patterning trenches with selected trench depth and selected lateral trench width into the said first crystal material, whereby said at least one first selected crystal stack is comprised of multiple first selected crystal stacks.

4. The method according to claim 3 further comprising the steps of:
(g) selecting one or more of the said first selected crystal stacks;
(h) physically isolating one or more of said first selected crystal stacks of step (g), thereby producing one or more second selected crystal stacks;
(i) supporting the said one or more second selected crystal stacks on a support structure suitable for additional crystal growth.
(j) carrying out additional growth of said one or more second selected crystal stacks such that said second crystal material above the said interface plane is allowed to grow and expand without impedance or coalescence with any other solid material; and
(k) continuing growth of said one or more second selected crystal stacks until a desired stack size and shape is achieved.

5. The method according to claim 4, wherein each of said one or more second crystal stacks selected for step (i) is supported by said suitable support structure that passes through a movable baffle plate that (1) can be positionable close to the growing said second crystal stack throughout said steps (j) and (k), (2) can allow material deposition on the baffle plate in the vicinity of the growing said second crystal stack during said steps (j) and (k), and (3) can be moveable away from the growing said second crystal stack during said crystal growth so as to prevent said material deposition on the said baffle plate from coalescing with the growing said second crystal stack.

6. The method according to claim 4, wherein said additional growth of steps (j) and (k) includes supplying gas flow, wherein said gas flow is for a vapor growth process, and wherein said gas flow is non-uniform in composition with respect to a concentration of precursors applied to each of said selected second crystal stacks so as to minimize precursor concentration in the vicinity of said support structure so as to minimize crystal growth in the vicinity of the said support structure.

7. The method according to claim 4, wherein said additional growth of steps (j) and (k) includes supplying gas flow, wherein said gas flow is for a vapor growth process and is directed toward the growing crystal at a location furthest from said support structure for said additional growth of each of said second crystals stacks.

8. The method according to claim 4, wherein each said second selected crystal stacks is comprised of a single crystal stack.

9. The method according to claim 4, wherein said step (g) is comprised of steps of:
(g1) performing an analysis that reveals crystal defects in said selected second crystal material within said first selected crystal stacks; and
(g2) based upon inspection of the results produced by step (g1), selecting the one or more of the said first crystal stacks that exhibit the lowest defect density within the said second crystal material.

10. The method according to claim 9, wherein said performed analysis is selected from the group of treatments comprising: a thermal oxidation technique, a defect-preferential chemical etch, an X-ray analysis technique, and a surface profilometry technique.

11. The method according to claim 4, wherein said physically isolating of said first crystal stacks is accomplished using a process selected from the group comprising cutting with a dicing saw, patterned dry etching, non-patterned dry etching, patterned wet etching, non-patterned wet etching, laser-based cutting, cleaving, mechanical lapping, and patterned application of a growth-inhibiting material.

12. The method according to claim 11, wherein at least one said selected processes for physically isolating said first selected crystal stacks is carried out on said bottom side of said first crystal, and wherein the bottom side of the said second crystal stack is defined to be the same side as the said bottom side of the said first crystal.

13. The method according to claim 12, wherein said processes are selected to be carried out by patterned etching of said first crystal bottom side, wherein the pattern is selected to have means to facilitate supporting said selected second crystal stack.

14. The method according to claim 13, wherein said selected pattern and said patterned etching are selected to produce a hole cavity in the said second crystal stack bottom side with a depth less than 80% of the height of the crystal stack.

15. The method according to claim 13, wherein said selected pattern and said patterned etching are selected to produce a hole cavity in the said second crystal stack bottom side that does not penetrate the said interface plane.

16. The method according to claim 12, wherein said selected process removes entirely said first crystal material so that second said selected crystal stack is comprised entirely of said selected second material.

17. The method according to claim 4, wherein said additional growth of steps (j) and (k) includes providing a support for said second selected crystal stack that does not reside above the said interface plane.

18. The method according to claim 1, wherein said first crystal material is selected from the group consisting of 4H—SiC, 6H—SiC, and 15R-SiC.

19. The method according to claim 1, wherein said second crystal material is selected from the group consisting of 3C—SiC, diamond, cubic-GaN, cubic-AlN, cubic-AlGaN, cubic-InN, cubic-InGaN.

20. The method according to claim 1, wherein said first set of selected growth conditions comprise a set of growth parameters comprising at least crystal temperature, reactor pressure, concentration of reactor precursors for material being deposited, concentration gradients of said reactor precursors, composition of carrier gas used in said reactor, and flow rate of carrier gas within said reactor.

21. The method according to claim 1, wherein said first set of selected growth conditions provide a growth process selected from the group consisting of chemical vapor deposition, physical vapor phase epitaxy, and sublimation processes.

22. The method according to claim 1, wherein said first set of selected growth conditions provides a growth process consisting of chemical vapor deposition.

23. The method according to claim 22, wherein said chemical vapor deposition is carried out using precursor gases that are silane and a hydrocarbon for the growth of silicon carbide.

24. The method according to claim 23, wherein the said second crystal material is 3C—SiC.

25. The method according to claim 24, wherein said second set of growth conditions for the crystal growth include a temperature in the range of 1000° C. to 2000° C.

26. The method according to claim 3, wherein said shape of said step-free top surfaces is selected to be devoid of concave border features.

27. The method according to claim 3, wherein the shape and orientation of said at least one step-free top surface is selected to conform to the preferred growth shape and orientation of said second crystal material on top of said first crystal.

28. The method according to claim 3, wherein growth of the said first crystal material toward said interface plane is prevented by selectively coating bottom of said trenches in said first crystal material with a growth inhibiting material.

29. The method according to claim 3, wherein said mesas are selected with said mesa height that exceeds said desired height of said second material.

30. The method according to claim 3, wherein said growth of the said first crystal material toward said interface plane is prevented by selectively applying a growth inhibiting material to the said trenches.

31. The method according to claim 1, wherein said selected second crystal material is 3C—SiC, and wherein said first crystal is a hexagonal polytype of silicon carbide with a stacking sequence and c-axis sequence repeat height, and wherein said single crystals of second crystal material has selected crystal orientation with respect to the said first crystal, and wherein said selected shape of said at least one step-free top surface is a triangle whose three sides are perpendicular to within 10 degrees to one of the two selected sets of three <1\overline{1}00> crystallographic directions with 120 degrees of angular separation, and wherein the following operational steps are carried out after said operational step (c) of claim 1 and before the initiation of said operational step (d) of claim 1;
(ci) providing a step-flow etch of said at least one step-free top surface with triangular shape so as to provide a sequence of concentric triangular plateaus wherein adjacent said plateaus are vertically separated by steps of said c-axis repeat height so that topmost two bilayers of said plateaus all have a selected stacking sequence;
(cii) depositing a homoepitaxial film on said sequence of concentric triangular plateaus under selected conditions so as to provide step-flow growth while suppressing two-dimensional nucleation; and
(ciii) continuing said deposition of said homoepitaxial film on said concentric triangular plateaus until said step-flow growth obtains an at least one step-free top surface that has topmost two bilayers of selected stacking sequence that defines at least one step-free interface plane.

32. The method according to claim 31, wherein said at least one step-free surface is comprised of an array of said step-free surfaces with triangular shape.

33. The method according to claim 32, wherein each three sides of said triangular shape step-free surfaces are perpendicular to within 10 degrees to the same said selected set of three <1100> crystallographic directions with 120 degrees of angular separation.

34. The method of 32 wherein said 3C—SiC material is used in the fabrication of semiconductor devices.

35. A method for the vapor phase crystal growth of a relatively large single crystal of a selected crystal material starting from a selected seed crystal of the same crystal material, wherein said method comprises the steps of:
(a) selecting a seed crystal whose chemical bonding structure is tetrahedral, whose crystal structure is cubic, and which is characterized by exhibiting the behavior that under selected crystal growth conditions said selected crystal subsequently exhibits homoepitaxial crystal growth by having step flow growth occurring at steps on the surfaces of said selected seed crystal initiated by an edge/corner nucleation mechanism at a rate that is more than the rate of crystal growth due to step flow growth at steps on the surfaces of said selected seed crystal initiated at defects in the said crystal,
(b) supporting the said selected seed crystal with a selected support structure in a manner that during subsequent crystal growth under said selected growth conditions, said crystal growth occurs without impedance or convergence of the growing crystal with any solid material that is external to said growing crystal,
(c) initiating crystal growth of said crystal material on said selected seed crystal under said first set of selected crystal growth conditions that yields homoepitaxial crystal growth of low-defect crystal by step-flow growth at steps on the surface of the selected seed crystal initiated by said edge/corner nucleation mechanism at a said rate that is more than said rate of crystal growth due to step-flow growth at steps on the surface of said selected seed crystal initiated at defects in the said selected seed crystal, and
(d) continuing said homoepitaxial crystal growth of said seed selected crystal in a selected manner so that said crystal growth occurs without impedance or convergence of the growing said seed crystal with solid materials external to said growing crystal until a desired shape and height of said single crystal is achieved forming at least one large low-defect crystal of said selected crystal material.

36. The method according to claim 35, wherein said seed crystal is supported by said suitable support structure that passes through a movable baffle plate that (1) can be positionable close to the growing said seed crystal throughout said homoepitaxial crystal growth, (2) can allow material deposition on the baffle plate in the vicinity of the growing said seed crystal during said homoepitaxial crystal growth, and (3) can be moveable away from the growing said seed crystal during said homoepitaxial crystal growth so as to prevent said material deposition on the said baffle plate from coalescing with the growing said seed crystal.

37. The method according to claim 35, wherein said homoepitaxial crystal growth includes supplying gas flow, wherein said gas flow is for a vapor growth process, and wherein said gas flow is non-uniform in composition with respect to a concentration of precursors applied to said seed crystal so as to minimize precursor concentration in the vicinity of said support structure so as to minimize crystal growth in the vicinity of the said support structure.

38. The method according to claim 37, wherein said selected growth conditions are such that said gas flow for said vapor growth process is directed toward the growing said seed crystal at a location furthest from said support structure so as to minimize growth in the vicinity of the support structure.

39. The method according to claim 35, wherein said selected growth conditions comprise a set of growth parameters comprising at least crystal temperature, reactor pressure, concentration of reactor precursors for material being deposited, concentration gradients of said reactor precursors, composition of carrier gas used in said reactor, and flow rate of carrier gas within said reactor.

40. The method according to claim 35, wherein said selected growth conditions provide a growth process selected from the group consisting of chemical vapor deposition, physical vapor phase epitaxy, and sublimation processes.

41. The method according to claim 35, wherein said seed crystal material is selected from the group consisting of 3C—SiC, diamond, cubic-GaN, cubic-AlN, cubic-AlGaN, cubic-InN, cubic-InGaN.

42. The method of claim 35, wherein said selected growth conditions provide a growth process consisting of chemical vapor deposition.

43. The method of claim 42, wherein said chemical vapor deposition is carried out using precursor gases that are silane and a hydrocarbon for the growth of silicon carbide.

44. The method of claim 43, wherein said seed crystal material is 3C—SiC.

45. The method of claim 44, wherein said growth conditions for crystal growth include a temperature in the range of 1000° C. to 2000° C.

46. A method for producing an array of 3C—SiC single crystals on a single crystal substrate having a crystal basal plane, wherein each of said 3C—SiC single crystals has a predetermined crystal orientation with respect to the said single crystal substrate, said method comprising the operational steps of:
(a) selecting said single-crystal substrate from hexagonal polytypes of silicon carbide that have two possible sets of three <1100> crystallographic directions with 120 degrees of angular separation;
b) preparing a planar first surface on said single-crystal substrate wherein said planar first surface is tilted by an angle of less than ten (10) degrees with respect to the crystal basal plane;
(c) removing material from said planar first surface so as to define a plurality of mesas with separated planar top second surfaces, wherein each of said separated planar top second surfaces is selected to be a triangle whose three sides are perpendicular to, within 10 degrees, one of the said two possible sets of three <1100> crystallographic directions with 120 degrees of angular separation;
(d) treating said separated planar top second surfaces of said mesas so as to remove any removable sources of unwanted crystal nucleation and any removable sources of steps from said separated planar top second surfaces;
(e) depositing a first homoepitaxial film over said separated planar top second surfaces of said mesas under selected first growth conditions so as to provide a step-flow growth while suppressing two-dimensional nucleation;
(f) continuing said deposition of said homoepitaxial film until said step-flow growth obtains first step-free epitaxial film surface on at least one of the said separated planar top second surfaces;
(g) providing a step-flow etch of said first step-free epitaxial film surfaces so as to provide concentric triangular plateaus having sequentially increasing heights and forming structural steps;
(h) depositing a second homoepitaxial film on said sequence of concentric triangular plateaus under selected second growth conditions so as to provide step-flow growth while suppressing two-dimensional nucleation;
(i) continuing said deposition of said second homoepitaxial film on said concentric triangular plateaus until said step-flow growth obtains a second step-free epitaxial film surface that defines a step-free interface plane for each mesa;
(j) initiating single-island heteroepitaxial crystal growth of bilayers of 3C—SiC on top of said step-free interface planes.
(k) continuing said crystal growth of additional 3C—SiC above the said interface planes under a third set of selected crystal growth conditions that yields homoepitaxial crystal growth of 3C—SiC by an edge/corner nucleation mechanism at a rate that is more than the rate of crystal growth due to step-flow growth at steps initiated at defects in said 3C—SiC single crystals;
(l) continuing said homoepitaxial 3C—SiC crystal growth in a selected manner so that said crystal growth occurs without impedance or convergence from other solid materials until the desired 3C—SiC crystal shape and height is achieved on each of said mesas.

47. The method according to claim 46, wherein said 3C—SiC crystals are used in the fabrication of semiconductor devices.

48. The method according to claim 46, wherein said selected first, second, and third growth conditions comprise a set of growth parameters comprising at least crystal temperature, reactor pressure used for said deposition, concentration of reactor precursors for material being deposited, concentration gradients of said reactor precursors, composition of carrier gas used in said reactor, and flow rate of carrier gas within said reactor.

49. The method according to claim 46, wherein said selected growth conditions provide a growth process selected from the group consisting of chemical vapor deposition, physical vapor phase epitaxy, and sublimation processes.

50. The method according to claim 46, wherein said selected growth conditions provide a growth process consisting of chemical vapor deposition.

51. The method according to claim 49, wherein said chemical vapor deposition is carried out using precursor gases that are silane and a hydrocarbon for the growth of silicon carbide.

52. The method according to claim 50, wherein the growth temperature is in the range 1000° C. to 2000° C.

53. The method according to claim 46, wherein said second selected growth conditions are selected to be the same as said first selected growth conditions.
